(19) United States
(12) Patent Application Publication
(10) Pub. No.: US 2018/0248100 A1
(43) Pub. Date: Aug. 30, 2018

(54) THERMOELECTRIC ELEMENT, THERMOELECTRIC MODULE AND METHOD OF MANUFACTURING THERMOELECTRIC ELEMENT

(71) Applicant: SHOWA DENKO K.K., Tokyo (JP)

(72) Inventors: Katsumi Toyama, Chichibu-shi (JP); Yasutaka Yoshida, Chichibu-shi (JP); Akifumi Muraoka, Chichibu-shi (JP)

(73) Assignee: SHOWA DENKO K.K., Tokyo (JP)

(21) Appl. No.: 15/885,917

(22) Filed: Feb. 1, 2018

(30) Foreign Application Priority Data
Feb. 6, 2017 (JP) 2017-019889

(51) Int. Cl. H01L 35/32; H01L 35/18; H01L 35/02

(52) U.S. Cl. CPC H01L 35/32; H01L 35/02; H01L 35/18

(57) ABSTRACT

Unevenness in thickness of a junction layer of a thermoelectric element including a thermoelectric conversion layer composed of an alloy having a filled skutterudite structure is reduced. The p-type thermoelectric element includes: a p-type thermoelectric conversion layer composed of an alloy having a filled skutterudite structure and containing antimony; a p-side first conductor layer composed of iron foil and laminated on the p-type thermoelectric conversion layer; a p-side second conductor layer composed of titanium foil and laminated on the p-side first conductor layer; and a p-side junction layer composed of copper foil and laminated on the p-side second conductor layer to be used for electrical junction with an electrode attached to a substrate.

### CROSS REFERENCE TO RELATED APPLICATIONS

This application is based on and claims priority under 35 USC § 119 from Japanese Patent Application No. 2017-019889 filed Feb. 6, 2017, incorporated herein by reference in its entirety.

### BACKGROUND

### Technical Field

The present invention relates to a thermoelectric element and a thermoelectric module.

### Related Art

There exists a thermoelectric module that converts between thermal energy and electric energy by use of a thermoelectric effect, such as Thomson effect, Peltier effect, Seebeck effect or the like.

In such a thermoelectric module, two kinds of thermoelectric elements each including a thermoelectric conversion layer made of a thermoelectric conversion material are used in combination. For example, in a thermoelectric module, plural p-type thermoelectric elements each including a p-type thermoelectric material and plural n-type thermoelectric elements each including an n-type thermoelectric material are connected in series by electrodes to be used.

Japanese Patent Application Laid-Open Publication 2016-92277 describes that, in preparing a thermoelectric element, a laminated body of a thermoelectric conversion layer made of a filled skutterudite alloy and a titanium layer laminated on the thermoelectric conversion layer is prepared by a discharge plasma sintering method using powder as a starting material, and on the titanium layer of the obtained sintered body, a titanium nitride layer, another titanium layer and a copper layer are laminated in this order by using a PVD (physical vapor deposition) method.

Incidentally, when a configuration, in which an intermediate layer composed of a sintered body made by sintering powder, a laminated body made by the PVD method or the like was provided between a thermoelectric conversion layer including the filled skutterudite structure and a junction layer used for electrical junction with the outside at an outermost layer to join the thermoelectric conversion layer and the junction layer, was adopted, since asperities were apt to be generated on an upper surface of the intermediate layer on which the junction layer was to be formed, unevenness occurred in the thickness of the junction layer in some cases.

The present invention has as an object to reduce unevenness in thickness of a junction layer of a thermoelectric element including a thermoelectric conversion layer composed of an alloy having a filled skutterudite structure.

### SUMMARY

A thermoelectric element according to the present invention includes: a thermoelectric conversion layer that is composed of an alloy including a filled skutterudite structure; a junction layer that is composed of metallic foil containing copper and used for electrical junction with outside; and an intermediate layer that is composed of metallic foil and provided between the thermoelectric conversion layer and the junction layer.

Here, the intermediate layer includes: a stress relaxation layer that is provided on a side facing the thermoelectric conversion layer to relax a stress of the thermoelectric conversion layer; and a diffusion suppression layer that is provided on a side facing the junction layer to suppress diffusion of elements between the thermoelectric conversion layer and the junction layer.

Moreover, when the thermoelectric conversion layer is composed of an alloy including a filled skutterudite structure represented by REₓ(Fe_{1-y}M_{y})₄Sb₁₂, where RE is at least one type selected from rare-earth elements, M is at least one type selected from a group of Co and Ni, 0.01≤x≤1, and 0≤y≤0.5, the stress relaxation layer of the intermediate layer is composed of metallic foil containing iron, and the diffusion suppression layer of the intermediate layer is composed of metallic foil containing titanium.

Further, when the thermoelectric conversion layer is composed of an alloy including a filled skutterudite structure represented by Rₓ(Co_{1-y}M_{y})₄Sb₁₂, where R is at least one type selected from group II elements or rare-earth elements, M is at least one type selected from a group of Fe and Ni, 0.01≤x≤1 and 0≤y≤0.3, the stress relaxation layer of the intermediate layer is composed of metallic foil containing cobalt or metallic foil containing nickel, and the diffusion suppression layer of the intermediate layer is composed of metallic foil containing titanium.

Moreover, from another standpoint, a thermoelectric element according to the present invention includes: a thermoelectric conversion layer that is composed of an alloy including a filled skutterudite structure containing a transition metal; a first intermediate layer that is composed of metallic foil containing a transition metal same as the transition metal contained in the thermoelectric conversion layer and laminated on the thermoelectric conversion layer; a second intermediate layer that is composed of metallic foil containing titanium and laminated on the first intermediate layer; and a junction layer that is composed of metallic foil containing copper and laminated on the second intermediate layer to be used for electrical junction with outside.

Further, from another standpoint, a thermoelectric element according to the present invention includes: a thermoelectric conversion layer that is composed of an alloy including a filled skutterudite structure containing cobalt and at least one type selected from group II elements or rare-earth elements; a junction layer that is composed of metallic foil containing copper and used for electrical junction with outside; and an intermediate layer essentially containing titanium, and further containing at least one of aluminum, iron, cobalt and nickel, and provided between the thermoelectric conversion layer and the junction layer.

Moreover, from another standpoint, a thermoelectric module according to the present invention includes: thermoelectric elements and electrodes electrically connected to the thermoelectric elements, wherein each of the thermoelectric elements includes: a thermoelectric conversion layer that is composed of an alloy including a filled skutterudite structure; a junction layer that is composed of metallic foil containing copper and used for electrical junction with one of the electrodes; and an intermediate layer that is composed of metallic foil and provided between the thermoelectric conversion layer and the junction layer.

Further, from another standpoint, a thermoelectric module according to the present invention includes: thermoelectric elements and electrodes electrically connected to the thermoelectric elements, wherein each of the thermoelectric elements includes: a thermoelectric conversion layer that is composed of an alloy including a filled skutterudite structure containing a transition metal; a first intermediate layer that is composed of metallic foil containing a transition metal same as the transition metal contained in the thermoelectric conversion layer and laminated on the thermoelectric conversion layer; a second intermediate layer that is composed of metallic foil containing titanium and laminated on the first intermediate layer; and a junction layer that is composed of metallic foil containing copper and laminated on the second intermediate layer to be used for electrical junction with outside.

Still further, from another standpoint, a thermoelectric module according to the present invention includes: thermoelectric elements and electrodes electrically connected to the thermoelectric elements, wherein each of the thermoelectric elements includes: a thermoelectric conversion layer that is composed of an alloy including a filled skutterudite structure containing cobalt and at least one type selected from group II elements or rare-earth elements; a junction layer that is composed of metallic foil containing copper and used for electrical junction with outside; and an intermediate layer essentially containing titanium, and further containing at least one of aluminum, iron, cobalt and nickel, and provided between the thermoelectric conversion layer and the junction layer.

Moreover, from still another standpoint, a method of manufacturing a thermoelectric element according to the present invention includes: laminating metallic foil containing copper, metallic foil containing titanium, metallic foil containing iron, alloy powder containing antimony, iron and rare-earth elements, the metallic foil containing iron, the metallic foil containing titanium and the metallic foil containing copper in this order to form a laminated material in a die; and performing spark plasma sintering of the laminated material in the die while applying pressure in a lamination direction of the laminated material.

Further, from still another standpoint, a method of manufacturing a thermoelectric element according to the present invention includes: laminating metallic foil containing copper, metallic foil containing titanium, metallic foil containing cobalt or metallic foil containing nickel, alloy powder containing antimony, cobalt and at least one type selected from group II elements or rare-earth elements, the metallic foil containing cobalt or the metallic foil containing nickel, the metallic foil containing titanium and the metallic foil containing copper in this order to form a laminated material in a die; and performing spark plasma sintering of the laminated material in the die while applying pressure in a lamination direction of the laminated material.

Still further, from still another standpoint, a method of manufacturing a thermoelectric element according to the present invention includes: laminating metallic foil containing copper, mixed powder containing titanium powder and powder of metal A, alloy powder containing antimony, cobalt and at least one type selected from group II elements or rare-earth elements, the mixed powder containing the titanium powder and the powder of the metal A, and the metallic foil containing copper in this order to form a laminated material in a die; and performing spark plasma sintering of the laminated material in the die while applying pressure in a lamination direction of the laminated material.

Here, the metal A contains at least one type selected from aluminum, iron, cobalt and nickel.

According to the present invention, it is possible to reduce unevenness in thickness of the junction layer of the thermoelectric element including the thermoelectric conversion layer composed of an alloy having a filled skutterudite structure.

### BRIEF DESCRIPTION OF THE DRAWINGS

Exemplary embodiments of the present invention will be described in detail based on the following figures, wherein:

FIG. 1 is a schematic view showing an example of a thermoelectric module to which the exemplary embodiments are applied;

FIG. 2 is a cross-sectional schematic view showing an example of a p-type thermoelectric element;

FIG. 3 is a cross-sectional schematic view showing an example of an n-type thermoelectric element;

FIG. 4 is a diagram showing an example of a method of preparing a p-type thermoelectric sintered body;

FIG. 5 is a diagram showing an example of a method of preparing an n-type thermoelectric sintered body;

FIG. 6 is a cross-sectional schematic view showing another example of the n-type thermoelectric element;

FIG. 7 is a diagram showing another example of the method of preparing the n-type thermoelectric sintered body;

FIG. 8A is a cross-sectional photograph of the p-type thermoelectric element of Example taken by an SEM (Scanning Electron Microscope), and

FIG. 8B is a cross-sectional photograph of a p-type thermoelectric element of Comparative Example taken by the SEM; and

FIG. 9A is a surface photograph of a p-side junction layer of Example taken by the SEM, and FIG. 9B is a surface photograph of a p-side junction layer of Comparative Example taken by the SEM.

### DETAILED DESCRIPTION

Hereinafter, exemplary embodiments according to the present invention will be described in detail with reference to attached drawings.

### Exemplary Embodiment 1

### [Thermoelectric Module]

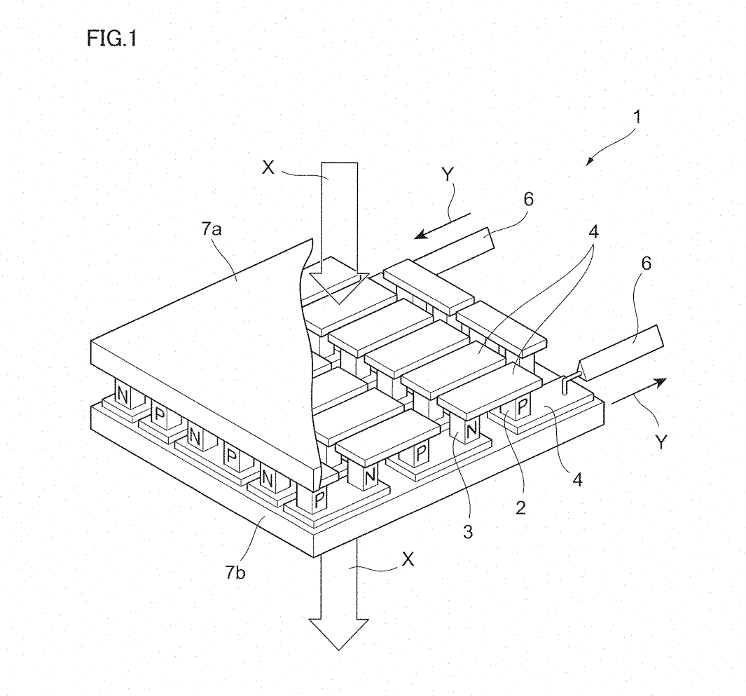

FIG. 1 is a schematic view showing an example of a thermoelectric module 1 to which the exemplary embodiment is applied.

In the thermoelectric module 1 of the exemplary embodiment, as shown in FIG. 1, plural p-type thermoelectric elements 2 and plural n-type thermoelectric elements 3 are disposed between two insulating substrates 7a and 7b vertically facing each other. The plural p-type thermoelectric elements 2 and the plural n-type thermoelectric elements 3 are alternately connected in series by plural electrodes 4, and attached to the respective substrates 7a and 7b via the electrodes 4. Moreover, of the plural p-type thermoelectric elements 2 and the plural n-type thermoelectric elements 3 connected in series, to the p-type thermoelectric element 2 positioned at one end and an n-type thermoelectric element 3 positioned at the other end, lead wires 6 are connected via the electrodes 4.

Note that, though a shape of each of the p-type thermoelectric element 2 and n-type thermoelectric element 3 is not particularly limited, the thermoelectric element is normally in a prismatic shape or in a columnar shape. In the thermoelectric module 1 shown in FIG. 1, each of the p-type thermoelectric element 2 and the n-type thermoelectric element 3 has the prismatic shape. Moreover, the side surfaces of each of the p-type thermoelectric element 2 and the n-type thermoelectric element 3 (surfaces not connected to the electrode 4) may be covered with a covering layer made of, for example, titanium nitride or the like.

Moreover, though illustration is omitted, in the thermoelectric module 1, a high-temperature side heat exchanger is disposed adjacent to one of the substrates 7a and a low-temperature side heat exchanger is disposed adjacent to the other substrate 7b.

In the thermoelectric module 1 of the exemplary embodiment, as indicated by arrows X, by applying heat by the high-temperature side heat exchanger and taking heat by the low-temperature side heat exchanger, a huge temperature difference occurs between the high-temperature side and the low-temperature side of the respective thermoelectric elements (the p-type thermoelectric elements 2 and the n-type thermoelectric elements 3), to thereby generate an electromotive force. Then, by applying an electrical resistance load between the two lead wires 6, current flows as indicated by arrows Y.

Note that, in the following description, in the thermoelectric module 1, the side on which the high-temperature side heat exchanger is provided is simply referred to as a high-temperature side and the side on which the low-temperature side heat exchanger is provided is simply referred to as a low-temperature side in some cases.

### [Electrode]

The electrode 4 in the exemplary embodiment is composed of a metal having high mechanical strength in high temperature, such as copper or iron. Moreover, in the thermoelectric module 1 of the exemplary embodiment, between the p-type thermoelectric element 2 or the n-type thermoelectric element 3 and the electrode 4, another layer for improving a joint property of the p-type thermoelectric element 2 or the n-type thermoelectric element 3 and the electrode 4 may be provided.

### [P-Type Thermoelectric Element]

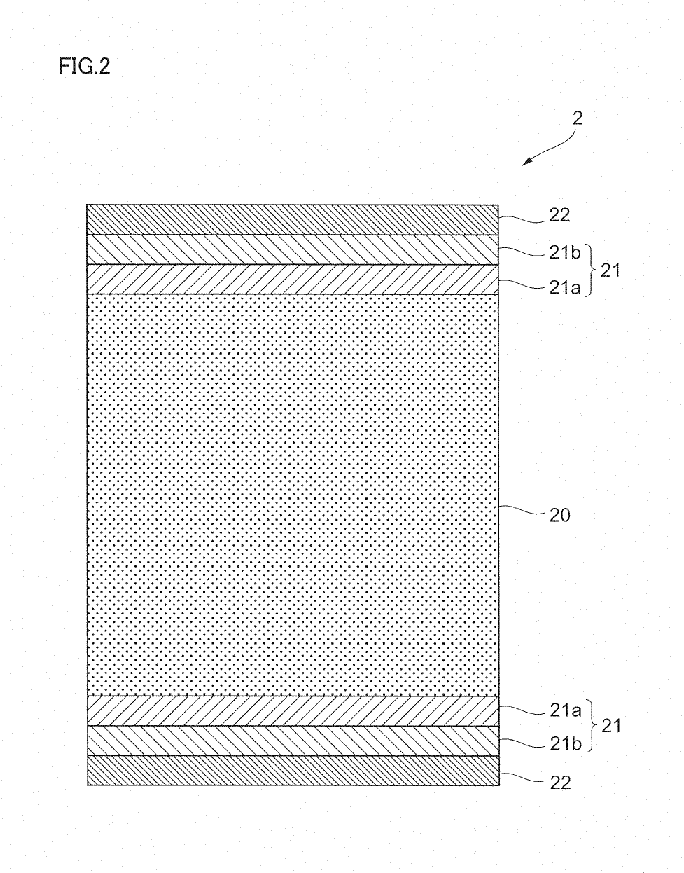

FIG. 2 is a cross-sectional schematic view showing an example of the p-type thermoelectric element 2.

The p-type thermoelectric element 2 as an example of the thermoelectric element includes: a p-type thermoelectric conversion layer 20 in which an electromotive force is generated by a temperature difference between the high-temperature side and the low-temperature side; p-side intermediate layers 21 laminated on respective two facing surfaces of the p-type thermoelectric conversion layer 20; and p-side junction layers 22 laminated on the respective p-side intermediate layers 21. Then, in the p-type thermoelectric element 2 of the exemplary embodiment, the above-described electrodes 4 (refer to FIG. 1) are joined onto the respective p-side junction layers 22 via a metal paste.

(P-Type Thermoelectric Conversion Layer)

As the p-type thermoelectric conversion layer 20 as an example of the thermoelectric conversion layer, a semiconductor composed of a filled skutterudite alloy represented by, for example, REₓ(Fe_{1-y}M_{y})₄Sb₁₂ (RE is at least one type selected from rare-earth elements, M is at least one type selected from a group of Co and Ni, 0.01≤x≤1, 0≤y≤0.5) can be adopted.

Here, as RE, it is preferable to use at least one type from La, Ce, Nd, Pr and Yb.

To specifically describe, in a filled skutterudite alloy containing antimony (Sb) that constitutes the p-type thermoelectric conversion layer 20 of the exemplary embodiment, a crystal structure is provided in which Sb elements are disposed at vertex positions of an octahedron to surround Fe elements and M elements (skutterudite structure). Then, a structure, in which RE elements are embedded in gaps formed among Fe elements, M elements and Sb elements forming the skutterudite structure, is provided. In the p-type thermoelectric conversion layer 20 of the exemplary embodiment, normally, a thermoelectric conversion is generated by Fe elements, M elements and Sb elements forming the skutterudite structure.

Note that the p-type thermoelectric conversion layer 20 may contain unavoidable impurities contained in raw materials. The crystal structure of the p-type thermoelectric conversion layer 20 can be confirmed by, for example, X-ray diffraction or the like.

When an alloy having the above-described filled skutterudite structure is used as the p-type thermoelectric conversion layer 20, x is preferably in a range of 0.01 or more and 1 or less, and y is preferably in a range of 0 or more and 0.5 or less.

When x is less than 0.01, since thermal conductivity of the p-type thermoelectric conversion layer 20 is increased and thereby the temperature difference between the high-temperature side and the low-temperature side of the p-type thermoelectric conversion layer 20 is reduced, there is a possibility of reduction of thermoelectric conversion efficiency. Moreover, when x exceeds 1, there is a possibility that rare-earth elements incapable of entering a crystal lattice are deposited, and electrical properties of the p-type thermoelectric conversion layer 20 is reduced.

Moreover, when y exceeds 0.5, there is a possibility that the Seebeck coefficient of the p-type thermoelectric conversion layer 20 is reduced.

(P-Side Intermediate Layer)

The p-side intermediate layer 21 as an example of an intermediate layer includes: a p-side first conductor layer 21a to be laminated on the p-type thermoelectric conversion layer 20; and a p-side second conductor layer 21b to be laminated on the p-side first conductor layer 21a and on which the p-side junction layer 22 is to be laminated.

(P-Side First Conductor Layer)

The p-side first conductor layer 21a as an example of a stress relaxation layer or a first intermediate layer is composed of metallic foil containing iron. Here, examples of the metallic foil containing iron include iron foil made of pure iron, alloy foil of iron and other metals. However, in terms of increasing suppressing effect of diffusion of antimony, which will be described later, it is preferable that the p-side first conductor layer 21a contains iron as a main component and that a content of impurities, such as metals other than iron or alloys of iron and other metals, is 45% by weight or less. When the content of impurities in the p-side first conductor layer 21a exceeds 45% by weight, there is a possibility that the suppressing effect of diffusion of antimony is reduced. Note that, even when the p-side first conductor layer 21a is composed of pure iron, the p-side first conductor layer 21a may contain unavoidable impurities contained in raw materials.

In the p-type thermoelectric element 2 of the exemplary embodiment, by providing the p-side first conductor layers 21a, cracking or peeling in each layer is suppressed in manufacturing processes of the p-type thermoelectric element 2, and thereby the yield of the p-type thermoelectric element 2 is improved.

Moreover, in the p-type thermoelectric element 2 of the exemplary embodiment, by providing the p-side first conductor layers 21a, it becomes possible to suppress diffusion of antimony from the p-type thermoelectric conversion layer 20 and to relax a thermal stress generated between the p-type thermoelectric conversion layer 20 and the p-side second conductor layers 21b.

This suppresses performance deterioration and breakage of the p-type thermoelectric element 2 or the thermoelectric module 1.

In other words, since the p-side first conductor layer 21a of the exemplary embodiment is composed to contain iron, antimony and iron react to generate an iron-antimony compound when antimony is released from the p-type thermoelectric conversion layer 20. As a result, antimony from the p-type thermoelectric conversion layer 20 is caught by the p-side first conductor layer 21a, and thereby diffusion of antimony from the p-type thermoelectric conversion layer 20 to the electrodes 4 can be suppressed.

Consequently, in the p-type thermoelectric element 2 of the exemplary embodiment, deterioration of thermoelectric performance of the p-type thermoelectric conversion layer 20 and performance deterioration of the electrodes 4 can be suppressed.

Note that, in the p-type thermoelectric element 2 of the exemplary embodiment, in some cases, an iron-antimony reaction layer composed of the iron-antimony compound is formed on a side of the p-side first conductor layer 21a that is in contact with the p-type thermoelectric conversion layer 20, due to reaction of antimony released from the p-type thermoelectric conversion layer 20 and iron in the p-side first conductor layer 21a. Moreover, in the p-type thermoelectric element 2 of the exemplary embodiment, thickness of the iron-antimony reaction layer is gradually increased in the p-side first conductor layer 21a in some cases due to repeated use of the thermoelectric module 1.

Normally, the iron-antimony compound is a substance possibly contained as impurities in the p-type thermoelectric conversion layer 20. Consequently, even when the iron-antimony compound is generated in the p-side first conductor layer 21a, troubles by the iron-antimony compound are less likely to occur in the p-type thermoelectric element 2.

The thickness of the p-side first conductor layer 21a is preferably, for example, 10 μm or more and 100 μm or less.

When the thickness of the p-side first conductor layer 21a is larger than 100 μm, the thickness of the p-type thermoelectric element 2 is increased, and thereby the thermoelectric module 1 is likely to be large sized. Moreover, heat transfer from the high-temperature side heat exchanger to the p-type thermoelectric conversion layer 20 or heat transfer from the p-type thermoelectric conversion layer 20 to the low-temperature side heat exchanger is suppressed, and thereby there is a possibility of reduction of the thermoelectric conversion efficiency in the p-type thermoelectric element 2. On the other hand, when the thickness of the p-side first conductor layer 21a is less than 10 μm, there is a possibility that effects of relaxing the thermal stress or catching antimony by the p-side first conductor layer 21a become insufficient.

(P-Side Second Conductor Layer)

The p-side second conductor layer 21b as an example of a diffusion suppression layer or a second intermediate layer is composed of metallic foil containing titanium. Here, examples of the metallic foil containing titanium include titanium foil made of pure titanium, alloy foil of titanium and other metals. However, in terms of increasing suppressing performance of diffusion of various types of elements, which will be described later, it is preferable that the p-side second conductor layer 21b contains titanium as a main component and that a content of impurities, such as metals other than titanium or alloys of titanium and other metals is 20% by weight or less. When the content of impurities contained in the p-side second conductor layer 21b exceeds 20% by weight, there is a possibility that an ability to suppress diffusion of antimony from the p-type thermoelectric conversion layer 20 or diffusion of elements from the electrode 4 or the like to the p-type thermoelectric conversion layer 20 and the p-side first conductor layer 21a is reduced. Note that, even when the p-side second conductor layer 21b is composed of pure titanium, the p-side second conductor layer 21b may contain unavoidable impurities contained in raw materials.

In the p-type thermoelectric element 2 of the exemplary embodiment, by providing the p-side second conductor layers 21b, it becomes possible to suppress diffusion of antimony from the p-type thermoelectric conversion layer 20 or diffusion of elements from the electrode 4 or the like to the p-type thermoelectric conversion layer 20 and the p-side first conductor layer 21a.

In the p-type thermoelectric element 2 of the exemplary embodiment, as described above, by providing the p-side first conductor layer 21a, antimony from the p-type thermoelectric conversion layer 20 and iron contained in the p-side first conductor layer 21a react with each other, and thereby it is possible to catch antimony from the p-type thermoelectric conversion layer 20 by the p-side first conductor layer 21a.

However, for example, when a large amount of antimony is diffused from the p-type thermoelectric conversion layer 20 or antimony is continuously diffused from the p-type thermoelectric conversion layer 20, it becomes difficult to catch all antimony by the p-side first conductor layer 21a in some cases.

To the contrary, in the exemplary embodiment, by providing the p-side second conductor layer 21b containing titanium, it becomes possible to shut off antimony by the p-side second conductor layer 21b, the antimony being released from the p-type thermoelectric conversion layer 20 and not being caught by the p-side first conductor layer 21a. This suppresses diffusion of antimony from the p-type thermoelectric conversion layer 20 to the electrode 4 via the p-side junction layer 22 in the p-type thermoelectric element 2. Moreover, in the thermoelectric module 1 of the exemplary embodiment, by providing the p-side second conductor layer 21b, diffusion of elements from the electrode 4 to the p-type thermoelectric element 2 can be suppressed.

As a result, it is possible to suppress reduction of thermoelectric conversion efficiency in the p-type thermoelectric conversion layer 20 of the p-type thermoelectric element 2 or performance deterioration of the electrode 4.

Note that, in the p-type thermoelectric element 2 of the exemplary embodiment, in some cases, a reaction layer composed of an alloy of titanium and antimony is formed on a side of the p-side second conductor layer 21b that is in contact with the p-side first conductor layer 21a, due to reaction of antimony released from the p-type thermoelectric conversion layer 20 and titanium in the p-side second conductor layer 21b.

The reaction layer also suppresses diffusion of antimony from the p-type thermoelectric conversion layer 20.

The thickness of the p-side second conductor layer 21b is preferably, for example, 10 μm or more and 100 μm or less.

When the thickness of the p-side second conductor layer 21b is larger than 100 μm, the thickness of the p-type thermoelectric element 2 is increased, and thereby the thermoelectric module 1 is likely to be large sized. On the other hand, when the thickness of the p-side second conductor layer 21b is less than 10 μm, there is a possibility that an effect of suppressing diffusion of elements between the p-type thermoelectric element 2 and the electrode 4 becomes insufficient.

(P-Side Junction Layer)

The p-side junction layer 22 as an example of a junction layer is composed of metallic foil containing copper. Here, examples of the metallic foil containing copper include copper foil made of pure copper, alloy foil of copper and other metals. However, in terms of increasing junction performance with the electrode 4, which will be described later, it is preferable that the p-side junction layer 22 contains copper as a main component and it is more preferable that the p-side junction layer 22 is made of pure copper. To describe more specifically, it is preferable that the content of copper in the p-side junction layer 22 is 60% by weight or more. When the content of copper in the p-side junction layer 22 is lower than 60% by weight, there is a possibility that joint strength with the p-side second conductor layer 21b is reduced. Note that, even when the p-side junction layer 22 is composed of pure copper, the p-side junction layer 22 may contain unavoidable impurities contained in raw materials.

The p-side junction layer 22 of the exemplary embodiment is provided to improve wettability of the metal paste, to thereby improve the joint property between the p-type thermoelectric element 2 and the electrode 4 when the electrode 4 is attached to the p-type thermoelectric element 2 via the metal paste, such as a silver paste.

The thickness of the p-side junction layer 22 is preferably, for example, 10 μm or more and 100 μm or less.

When the thickness of the p-side junction layer 22 is larger than 100 μm, the thickness of the p-type thermoelectric element 2 is increased, and thereby the thermoelectric module 1 is likely to be large sized. On the other hand, when the thickness of the p-side junction layer 22 is less than 10 μm, a portion with loss of the p-side junction layer 22 is generated, and accordingly, there is a possibility that joint strength between the p-type thermoelectric element 2 and the electrode 4 is reduced.

### [N-Type Thermoelectric Element]

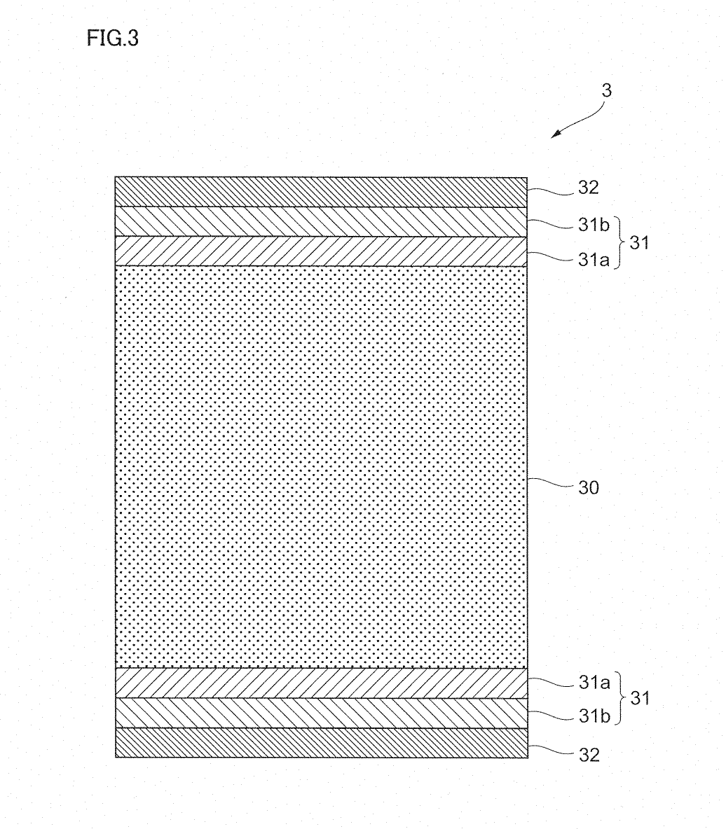

FIG. 3 is a cross-sectional schematic view showing an example of the n-type thermoelectric element 3.

The n-type thermoelectric element 3 as an example of the thermoelectric element includes: an n-type thermoelectric conversion layer 30 in which an electromotive force is generated by a temperature difference between the high-temperature side and the low-temperature side; n-side intermediate layers 31 laminated on respective two facing surfaces of the n-type thermoelectric conversion layer 30; and n-side junction layers 32 laminated on the respective n-side intermediate layers 31. Then, in the n-type thermoelectric element 3 of the exemplary embodiment, the above-described electrodes 4 (refer to FIG. 1) are joined onto the respective n-side junction layers 32 via a metal paste.

(N-Type Thermoelectric Conversion Layer)

As the n-type thermoelectric conversion layer 30 as an example of the thermoelectric conversion layer, a semiconductor composed of a filled skutterudite alloy represented by, for example, Rₓ(Co_{1-y}M_{y})₄Sb₁₂ (R is at least one type selected from group II elements or rare-earth elements, M is at least one type selected from a group of Fe and Ni, 0.01≤x≤1, 0≤y≤0.3) can be adopted.

Here, as R, it is preferable to use at least one type from Ca, Sr, Ba, La, Ce, Nd, Pr and Yb.

To specifically describe, in a filled skutterudite alloy containing antimony (Sb) that constitutes the n-type thermoelectric conversion layer 30 of the exemplary embodiment, a crystal structure is provided in which Sb elements are disposed at vertex positions of an octahedron to surround Co elements and M elements (skutterudite structure). Then, a structure, in which R elements are embedded in gaps formed among Co elements, M elements and Sb elements forming the skutterudite structure, is provided. In the n-type thermoelectric conversion layer 30 of the exemplary embodiment, normally, a thermoelectric conversion is generated by Co elements, M elements and Sb elements forming the skutterudite structure.

Note that the n-type thermoelectric conversion layer 30 may contain unavoidable impurities contained in raw materials. The crystal structure of the n-type thermoelectric conversion layer 30 can be confirmed by, for example, X-ray diffraction or the like.

When an alloy of the above-described filled skutterudite type is used as the n-type thermoelectric conversion layer 30, x is preferably in a range of 0.01 or more and 1 or less, and y is preferably in a range of 0 or more and 0.3 or less.

When x is less than 0.01, since thermal conductivity of the n-type thermoelectric conversion layer 30 is increased and thereby the temperature difference between the high-temperature side and the low-temperature side of the n-type thermoelectric conversion layer 30 is reduced, there is a possibility of deterioration of properties of the n-type thermoelectric element 3. Moreover, when x exceeds 1, there is a possibility that R elements incapable of entering a crystal lattice are deposited, and electrical properties of the n-type thermoelectric conversion layer 30 is reduced.

Moreover, when y exceeds 0.3, there is a possibility that the Seebeck coefficient of the n-type thermoelectric conversion layer 30 is reduced.

(N-Side Intermediate Layer)

The n-side intermediate layer 31 as an example of the intermediate layer includes: an n-side first conductor layer 31a to be laminated on the n-type thermoelectric conversion layer 30; and an n-side second conductor layer 31b to be laminated on the n-side first conductor layer 31a and on which the n-side junction layer 32 is to be laminated.

(N-Side First Conductor Layer)

The n-side first conductor layer 31a as an example of the stress relaxation layer or the first intermediate layer is composed of metallic foil containing cobalt or metallic foil containing nickel. Here, examples of the metallic foil containing cobalt include cobalt foil made of pure cobalt, alloy foil of cobalt and other metals. Moreover, examples of the metallic foil containing nickel include nickel foil made of pure nickel, alloy foil of nickel and other metals. However, in terms of increasing suppressing effect of diffusion of antimony, which will be described later, it is preferable that the n-side first conductor layer 31a contains cobalt as a main component when metallic foil containing cobalt is used, and that a content of impurities, such as metals other than cobalt or alloys of cobalt and other metals, is 45% by weight or less. Moreover, in similar terms, it is preferable that the n-side first conductor layer 31a contains nickel as a main component when metallic foil containing nickel is used, and that a content of impurities, such as metals other than nickel or alloys of nickel and other metals, is 45% by weight or less. When the content of impurities in the n-side first conductor layer 31a exceeds 45% by weight, there is a possibility that a prevention effect of diffusion of antimony is deteriorated. Note that, even when the n-side first conductor layer 31a is composed of pure cobalt or pure nickel, the n-side first conductor layer 31a may contain unavoidable impurities contained in raw materials.

In the n-type thermoelectric element 3 of the exemplary embodiment, by providing the n-side first conductor layers 31a, cracking or peeling in each layer is suppressed in manufacturing processes of the n-type thermoelectric element 3, and thereby the yield of the n-type thermoelectric element 3 is improved.

Moreover, in the n-type thermoelectric element 3 of the exemplary embodiment, by providing the n-side first conductor layers 31a, it becomes possible to suppress diffusion of antimony from the n-type thermoelectric conversion layer 30 and to relax a thermal stress generated between the n-type thermoelectric conversion layer 30 and the n-side second conductor layers 31b.

This suppresses performance deterioration and breakage of the n-type thermoelectric element 3 or the thermoelectric module 1.

In other words, since the n-side first conductor layer 31a of the exemplary embodiment is composed to contain cobalt or nickel, antimony reacts with cobalt or nickel to generate a cobalt-antimony compound or a nickel-antimony compound when antimony is released from the n-type thermoelectric conversion layer 30. As a result, antimony from the n-type thermoelectric conversion layer 30 is caught by the n-side first conductor layer 31a, and thereby diffusion of antimony from the n-type thermoelectric conversion layer 30 to the electrodes 4 can be suppressed.

Consequently, in the n-type thermoelectric element 3 of the exemplary embodiment, deterioration of thermoelectric performance of the n-type thermoelectric conversion layer 30 and performance deterioration of the electrodes 4 can be suppressed.

Note that the cobalt-antimony compound or the nickel-antimony compound is a substance possibly contained as impurities in the n-type thermoelectric conversion layer 30. Consequently, even when the cobalt-antimony compound or the nickel-antimony compound is generated in the n-side first conductor layer 31a, troubles by the cobalt-antimony compound or the nickel-antimony compound are less likely to occur in the n-type thermoelectric element 3.

The thickness of the n-side first conductor layer 31a is preferably, for example, 10 μm or more and 100 μm or less.

When the thickness of the n-side first conductor layer 31a is larger than 100 μm, the thickness of the n-type thermoelectric element 3 is increased, and thereby the thermoelectric module 1 is likely to be large sized. Moreover, heat transfer from the high-temperature side heat exchanger to the n-type thermoelectric conversion layer 30 or heat transfer from the n-type thermoelectric conversion layer 30 to the low-temperature side heat exchanger is suppressed, and thereby there is a possibility of reduction of the thermoelectric conversion efficiency in the n-type thermoelectric element 3. On the other hand, when the thickness of the n-side first conductor layer 31a is less than 10 μm, there is a possibility that effects of relaxing the thermal stress or catching antimony by the n-side first conductor layer 31a become insufficient.

(N-Side Second Conductor Layer)

The n-side second conductor layer 31b as an example of the diffusion suppression layer or the second intermediate layer is composed of metallic foil containing titanium. Here, examples of the metallic foil containing titanium include titanium foil made of pure titanium, alloy foil of titanium and other metals. However, in terms of increasing suppressing performance of diffusion of various types of elements, which will be described later, it is preferable that the n-side second conductor layer 31b contains titanium as a main component and that a content of impurities, such as metals other than titanium or alloys of titanium and other metals is 20% by weight or less. When the content of impurities contained in the n-side second conductor layer 31b exceeds 20% by weight, there is a possibility that an ability to suppress diffusion of antimony from the n-type thermoelectric conversion layer 30 or diffusion of elements from the electrode 4 or the like to the n-type thermoelectric conversion layer 30 and the n-side first conductor layer 31a is reduced. Note that, even when the n-side second conductor layer 31b is composed of pure titanium, the n-side second conductor layer 31b may contain unavoidable impurities contained in raw materials.

In the n-type thermoelectric element 3 of the exemplary embodiment, by providing the n-side second conductor layers 31b, it becomes possible to suppress diffusion of antimony from the n-type thermoelectric conversion layer 30 or diffusion of elements from the electrode 4 or the like to the n-type thermoelectric conversion layer 30 and the n-side first conductor layer 31a.

In the n-type thermoelectric element 3 of the exemplary embodiment, as described above, by providing the n-side first conductor layer 31a, antimony from the n-type thermoelectric conversion layer 30 and cobalt or nickel contained in the n-side first conductor layer 31a react with each other, and thereby it is possible to catch antimony from the n-type thermoelectric conversion layer 30 by the n-side first conductor layer 31a.

However, for example, when a large amount of antimony is diffused from the n-type thermoelectric conversion layer 30 or antimony is continuously diffused from the n-type thermoelectric conversion layer 30, it becomes difficult to catch all antimony by the n-side first conductor layer 31a in some cases.

To the contrary, in the exemplary embodiment, by providing the n-side second conductor layer 31b containing titanium, it becomes possible to shut off antimony by the n-side second conductor layer 31b, the antimony being released from the n-type thermoelectric conversion layer 30 and not being caught by the n-side first conductor layer 31a. This suppresses diffusion of antimony from the n-type thermoelectric conversion layer 30 to the electrode 4 via the n-side junction layer 32 in the n-type thermoelectric element 3. Moreover, in the thermoelectric module 1 of the exemplary embodiment, by providing the n-side second conductor layer 31b, diffusion of elements from the electrode 4 to the n-type thermoelectric element 3 can be suppressed.

As a result, it is possible to suppress deterioration of thermoelectric conversion efficiency in the n-type thermoelectric conversion layer 30 of the n-type thermoelectric element 3 or performance deterioration of the electrode 4.

Note that, in the n-type thermoelectric element 3 of the exemplary embodiment, in some cases, a reaction layer composed of an alloy of titanium and antimony is formed on a side of the n-side second conductor layer 31b that is in contact with the n-side first conductor layer 31a, due to reaction of antimony released from the n-type thermoelectric conversion layer 30 and titanium in the n-side second conductor layer 31b.

The reaction layer also suppresses diffusion of antimony from the n-type thermoelectric conversion layer 30.

The thickness of the n-side second conductor layer 31b is preferably, for example, 10 μm or more and 100 μm or less.

When the thickness of the n-side second conductor layer 31b is larger than 100 μm, the thickness of the n-type thermoelectric element 3 is increased, and thereby the thermoelectric module 1 is likely to be large sized. On the other hand, when the thickness of the n-side second conductor layer 31b is less than 10 μm, there is a possibility that an effect of suppressing diffusion of elements between the n-type thermoelectric element 3 and the electrode 4 becomes insufficient.

(N-Side Junction Layer)

The n-side junction layer 32 as an example of the junction layer is composed of metallic foil containing copper. Here, examples of the metallic foil containing copper include copper foil made of pure copper, alloy foil of copper and other metals. However, in terms of increasing junction performance with the electrode 4, which will be described later, it is preferable that the n-side junction layer 32 contains copper as a main component and it is more preferable that the n-side junction layer 32 is made of pure copper. To describe more specifically, it is preferable that the content of copper in the n-side junction layer 32 is 60% by weight or more. Note that, even when the n-side junction layer 32 is composed of pure copper, the n-side junction layer 32 may contain unavoidable impurities contained in raw materials.

The n-side junction layer 32 of the exemplary embodiment is provided to improve wettability of the metal paste, to thereby improve the joint property between the n-type thermoelectric element 3 and the electrode 4 when the electrode 4 is attached to the n-type thermoelectric element 3 via the metal paste, such as a silver paste.

The thickness of the n-side junction layer 32 is preferably, for example, 10 μm or more and 100 μm or less.

When the thickness of the n-side junction layer 32 is larger than 100 μm, the thickness of the n-type thermoelectric element 3 is increased, and thereby the thermoelectric module 1 is likely to be large sized. On the other hand, when the thickness of the n-side junction layer 32 is less than 10 μm, a portion with loss of the n-side junction layer 32 is generated, and accordingly, there is a possibility that joint strength between the n-type thermoelectric element 3 and the electrode 4 is reduced.

[Method of Manufacturing p-Type Thermoelectric Element]

A method of manufacturing the p-type thermoelectric element 2 will be described.

Here, the p-type thermoelectric element 2 of the exemplary embodiment is obtained through the respective processes below.

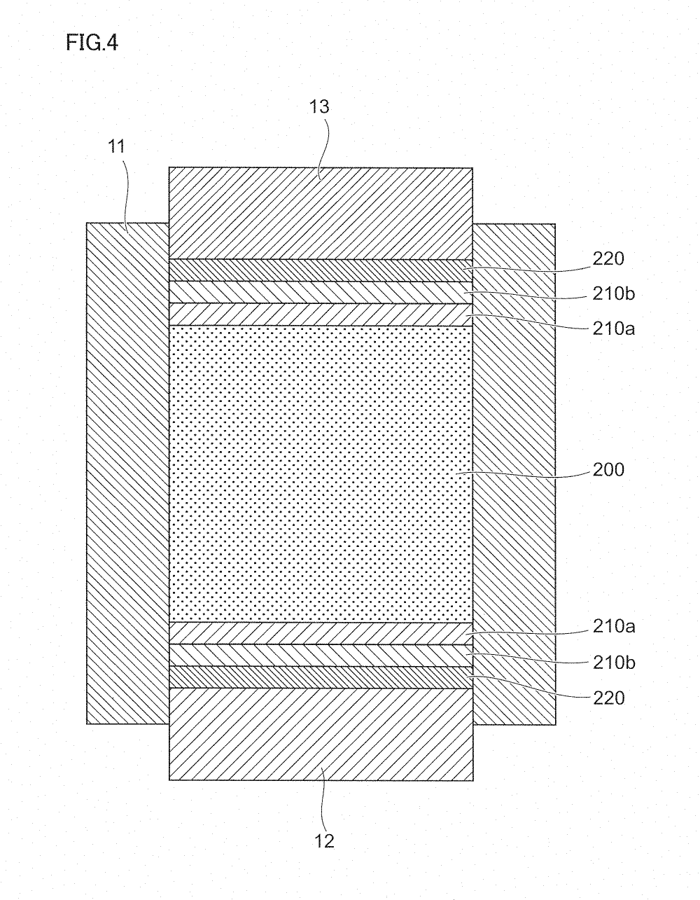

(1) “Preparation of p-type alloy powder 200 (refer to FIG. 4 to be described later”, where the p-type alloy powder 200 serves as a raw material of the p-type thermoelectric conversion layer 20
(2) “Preparation of p-type thermoelectric sintered body”, where the p-type thermoelectric sintered body serves as a base of the p-type thermoelectric element 2
(3) “Preparation of p-type thermoelectric element 2” by use of the p-type thermoelectric sintered body

Hereinafter, each process will be described.

(Preparation of p-Type Alloy Powder)

The p-type alloy powder 200 as an example of alloy powder, which contains antimony, iron and rare-earth elements to serve as a raw material of the p-type thermoelectric conversion layer 20, can be prepared by casting, for example, as follows.

First, each of RE (at least one type selected from the rare-earth elements), Fe and M (at least one type selected from a group of Co and Ni) as an example of transition metal, and antimony, which serve as a raw material of the p-type alloy powder 200 constituting the p-type thermoelectric conversion layer 20, is weighed to be mixed. Here, as a mixing ratio of each material, in consideration of loss in the later processes or the like, it is preferable that antimony is excessively formulated as compared to a stoichiometric composition ratio of the p-type thermoelectric conversion layer 20 to be finally obtained. This is because antimony is easily diffused, and, when the p-type thermoelectric conversion layer 20 is running short of antimony, troubles, such as reduction of the thermoelectric conversion efficiency in the p-type thermoelectric conversion layer 20, are likely to occur.

Subsequently, each material having been weighed is put into a crucible made of alumina or the like to be heated and melted. Note that the melting temperature can be set at, for example, of the order of 1450° C. Next, the melted materials are rapidly cooled by use of a strip casting method to be alloyed. In the strip casting method, materials melted in an argon atmosphere are cooled by being poured into a water-cooled rotating roll, to thereby obtain a rapidly solidified alloy with a thickness of the order of 0.1 mm to 0.5 mm. The cooling speed can be set, for example, in a range of 500° C./sec to 2000° C./sec.

Then, by milling the obtained rapidly solidified alloy, the p-type alloy powder 200 containing RE (at least one type selected from the rare-earth elements), iron and M (at least one type selected from a group of Co and Ni) and antimony, which serves as a raw material of the p-type thermoelectric conversion layer 20, can be obtained.

Here, it is preferable that an average particle diameter of the p-type alloy powder 200 is 5 μm to 200 μm. When the average particle diameter of the p-type alloy powder 200 is excessively small, an oxidation is likely to occur in sintering or the like; accordingly, there is a possibility that desired characteristics cannot be obtained in the p-type thermoelectric conversion layer 20. On the other hand, when the average particle diameter of the p-type alloy powder 200 is excessively large, the p-type thermoelectric conversion layer 20 to be obtained is likely to be coarse-grained, and is apt to have gaps. As a result, the mechanical strength of the p-type thermoelectric conversion layer 20 is reduced, and the p-type thermoelectric conversion layer 20 becomes prone to breakage in using the thermoelectric module 1.

(Preparation of p-Type Thermoelectric Sintered Body)

In the exemplary embodiment, the p-type thermoelectric sintered body is prepared by using a spark plasma sintering (SPS) method that applies mechanical pressure and pulsed ohmic heating to various types of raw materials constituting the p-type thermoelectric element 2 to sinter thereof.

FIG. 4 is a diagram for illustrating a method of preparing the p-type thermoelectric sintered body. To describe more specifically, FIG. 4 shows a cross-sectional configuration of the various types of raw materials of the p-type thermoelectric sintered body before sintering.

In a spark plasma sintering device, a die 11 in a cylindrical shape provided with a through hole in a columnar shape; a lower punch 12 in a columnar shape to be fit into the cylinder of the die 11 for closing a lower opening portion of the die 11; and an upper punch 13 in a columnar shape to be fit into the cylinder of the die 11 for closing an upper opening portion thereof are used. Here, each of the die 11, the lower punch 12 and the upper punch 13 is composed of graphite having conductivity. Then, in a state of applying pressure by sandwiching the raw materials for sintering that are disposed inside the die 11 between the lower punch 12 and the upper punch 13, plasma arc is generated by supplying DC pulse current to the lower punch 12 and the upper punch 13, to thereby prepare a sintered body.

In preparation of the p-type thermoelectric sintered body, as the raw materials of the p-type thermoelectric sintered body, the above-described p-type alloy powder 200, two sheets of p-side first metallic foil 210a, two sheets of p-side second metallic foil 210b, and two sheets of p-side third metallic foil 220 are used.

Of these, as the p-side first metallic foil 210a serving as a raw material of the p-side first conductor layer 21a, metallic foil containing iron is used. The thickness of the p-side first metallic foil 210a is preferably, for example, 10 μm or more and 100 μm or less.

Moreover, as the p-side second metallic foil 210b serving as a raw material of the p-side second conductor layer 21b, metallic foil containing titanium is used. The thickness of the p-side second metallic foil 210b is preferably, for example, 10 μm or more and 100 μm or less.

Further, as the p-side third metallic foil 220 serving as a raw material of the p-side junction layer 22, metallic foil containing copper is used. The thickness of the p-side third metallic foil 220 is preferably, for example, 10 μm or more and 100 μm or less.

These types of raw materials are disposed, inside the die 11 between the lower punch 12 and the upper punch 13, in the order of the p-side third metallic foil 220, the p-side second metallic foil 210b, the p-side first metallic foil 210a, the p-type alloy powder 200, the p-side first metallic foil 210a, the p-side second metallic foil 210b and the p-side third metallic foil 220 from the lower punch 12 side. On this occasion, a lower surface of the p-side third metallic foil 220 positioned relatively downward is in contact with an upper surface of the lower punch 12, and an upper surface of the p-side third metallic foil 220 positioned relatively upward is in contact with a lower surface of the upper punch 13.

Next, the object in the state shown in FIG. 4 is set in a not-shown spark plasma sintering device, and, in a vacuum or an inert gas, such as argon, pulse current is supplied to generate the plasma arc while applying pressure to the laminated body of the raw materials in the die 11 via the lower punch 12 and the upper punch 13, to thereby perform spark plasma sintering. In the case of the p-type thermoelectric sintered body of the exemplary embodiment, it is preferable to set the pressure in the spark plasma sintering to the range of 40 MPa to 60 MPa, and to set the sintering temperature of the order of 600° C.

In this manner, by the spark plasma sintering, the p-type thermoelectric sintered body can be obtained by laminating the p-side junction layer 22 made of the p-side third metallic foil 220, the p-side second conductor layer 21b made of the p-side second metallic foil 210b, the p-side first conductor layer 21a made of the p-side first metallic foil 210a, the p-type thermoelectric conversion layer 20 made of the p-type alloy powder 200, the p-side first conductor layer 21a made of the p-side first metallic foil 210a, the p-side second conductor layer 21b made of the p-side second metallic foil 210b, and the p-side junction layer 22 made of the p-side third metallic foil 220 in this order and consolidating thereof. At this time, the obtained p-type thermoelectric sintered body shows a disc shape (a tablet shape).

(Preparation of p-Type Thermoelectric Element)

The p-type thermoelectric sintered body obtained by the above-described procedures is cut and divided into plural p-type thermoelectric elements 2. The cutting method of the p-type thermoelectric sintered body is not particularly limited, but a band saw, a wire saw, or the like is used. Moreover, each of the divided p-type thermoelectric sintered body can be, for example, in a rectangular-parallelepiped shape.

Through the above processes, the p-type thermoelectric element 2 shown in FIG. 2 can be obtained.

[Method of Manufacturing n-Type Thermoelectric Element]

Subsequently, a method of manufacturing the n-type thermoelectric element 3 will be described.

Here, similar to the above-described p-type thermoelectric element 2, the n-type thermoelectric element 3 of the exemplary embodiment is obtained through the respective processes below.

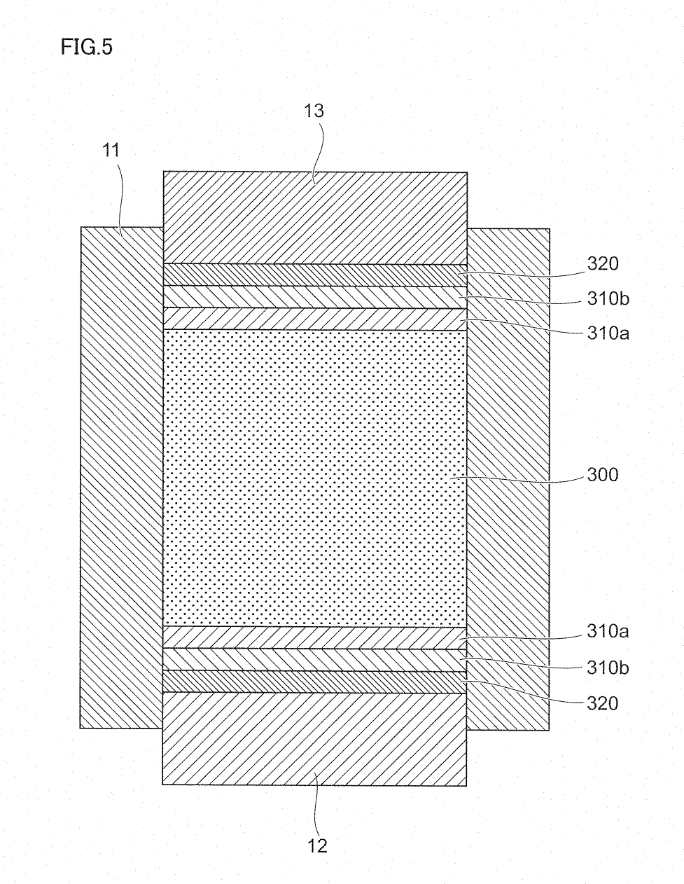

(1) “Preparation of n-type alloy powder 300 (refer to FIG. 5 to be described later”, where the n-type alloy powder 300 serves as a raw material of the n-type thermoelectric conversion layer 30
(2) “Preparation of n-type thermoelectric sintered body”, where the n-type thermoelectric sintered body serves as a base of the n-type thermoelectric element 3
(3) “Preparation of n-type thermoelectric element 3” by use of the n-type thermoelectric sintered body

Hereinafter, each process will be described.

(Preparation of n-Type Alloy Powder)

Similar to the aforementioned p-type alloy powder 200, the n-type alloy powder 300 as an example of the alloy powder, which contains antimony, cobalt and at least one type selected from group II elements or rare-earth elements to serve as a raw material of the n-type thermoelectric conversion layer 30, can be prepared by casting, for example. However, the preparation is different from the preparation of the p-type alloy powder 200 in the point that, as the raw materials of the n-type alloy powder 300, R (at least one type selected from the group II elements or the rare-earth elements), cobalt and M (at least one type selected from a group of Fe and Ni) as an example of transition metal, and antimony are used.

Here, it is preferable that an average particle diameter of the n-type alloy powder 300 is 5 μm to 200 μm. When the average particle diameter of the n-type alloy powder 300 is excessively small, an oxidation is likely to occur in sintering or the like; accordingly, there is a possibility that desired characteristics cannot be obtained in the n-type thermoelectric conversion layer 30. On the other hand, when the average particle diameter of the n-type alloy powder 300 is excessively large, the n-type thermoelectric conversion layer 30 to be obtained is likely to be coarse-grained, and is apt to have gaps. As a result, the mechanical strength of the n-type thermoelectric conversion layer 30 is reduced, and the n-type thermoelectric conversion layer 30 becomes prone to breakage in using the thermoelectric module 1.

Note that the method of preparing the p-type alloy powder 200 or the n-type alloy powder 300 is not limited to the above-described method; the alloy powder may be prepared by, for example, an atomizing method or the like. Moreover, it may be possible to calcine and crush mixed powder that is made by mixing weighed powder of various types of raw materials to be used as a raw material of the p-type thermoelectric conversion layer 20 or the n-type thermoelectric conversion layer 30.

(Preparation of n-Type Thermoelectric Sintered Body)

In the exemplary embodiment, similar to the above-described p-type thermoelectric sintered body, the n-type thermoelectric sintered body is prepared by use of the spark plasma sintering method.

FIG. 5 is a diagram for illustrating the method of preparing the n-type thermoelectric sintered body. To describe more specifically, FIG. 5 shows a cross-sectional configuration of the various types of raw materials of the n-type thermoelectric sintered body before sintering.

In preparation of the n-type thermoelectric sintered body, as the raw materials of the n-type thermoelectric sintered body, the above-described n-type alloy powder 300, two sheets of n-side first metallic foil 310a, two sheets of n-side second metallic foil 310b, and two sheets of n-side third metallic foil 320 are used.

Of these, as the n-side first metallic foil 310a serving as a raw material of the n-side first conductor layer 31a, metallic foil containing cobalt or metallic foil containing nickel is used. The thickness of the n-side first metallic foil 310a is preferably, for example, 10 μm or more and 100 μm or less.

Moreover, as the n-side second metallic foil 310b serving as a raw material of the n-side second conductor layer 31b, metallic foil containing titanium is used. The thickness of the n-side second metallic foil 310b is preferably, for example, 10 μm or more and 100 μm or less.

Further, as the n-side third metallic foil 320 serving as a raw material of the n-side junction layer 32, metallic foil containing copper is used. The thickness of the n-side third metallic foil 320 is preferably, for example, 10 μm or more and 100 μm or less.

These types of raw materials are disposed, inside the die 11 between the lower punch 12 and the upper punch 13, in the order of the n-side third metallic foil 320, the n-side second metallic foil 310b, the n-side first metallic foil 310a, the n-type alloy powder 300, the n-side first metallic foil 310a, the n-side second metallic foil 310b and the n-side third metallic foil 320 from the lower punch 12 side. On this occasion, a lower surface of the n-side third metallic foil 320 positioned relatively downward is in contact with an upper surface of the lower punch 12, and an upper surface of the n-side third metallic foil 320 positioned relatively upward is in contact with a lower surface of the upper punch 13.

Next, similar to the case of the p-type thermoelectric sintered body, the object in the state shown in FIG. 5 is set in the not-shown spark plasma sintering device, to thereby perform spark plasma sintering. In the case of the n-type thermoelectric sintered body of the exemplary embodiment, it is preferable to set the pressure in the spark plasma sintering to the range of 40 MPa to 60 MPa, and to set the sintering temperature of the order of 700° C.

In this manner, by the spark plasma sintering, the n-type thermoelectric sintered body can be obtained by laminating the n-side junction layer 32 made of the n-side third metallic foil 320, the n-side second conductor layer 31b made of the n-side second metallic foil 310b, the n-side first conductor layer 31a made of the n-side first metallic foil 310a, the n-type thermoelectric conversion layer 30 made of the n-type alloy powder 300, the n-side first conductor layer 31a made of the n-side first metallic foil 310a, the n-side second conductor layer 31b made of the n-side second metallic foil 310b, and the n-side junction layer 32 made of the n-side third metallic foil 320 in this order and consolidating thereof. At this time, the obtained n-type thermoelectric sintered body shows a disc shape (a tablet shape).

(Preparation of n-Type Thermoelectric Element)

The n-type thermoelectric sintered body obtained by the above-described procedures is cut and divided into plural n-type thermoelectric elements 3. The cutting method of the n-type thermoelectric sintered body is not particularly limited, but a band saw, a wire saw, or the like is used. Moreover, each of the divided n-type thermoelectric sintered body can be, for example, in a rectangular-parallelepiped shape.

Through the above processes, the n-type thermoelectric element 3 shown in FIG. 3 can be obtained.

### [Method of Manufacturing Thermoelectric Module]

Subsequently, a description will be given of an example of a method of preparing the thermoelectric module 1 by use of the p-type thermoelectric elements 2 and the n-type thermoelectric elements 3 prepared by the above-described methods.

When the thermoelectric module 1 is to be prepared, first, on each of substrates 7a and 7b having insulation property and composed of a ceramic or the like, the plural electrodes 4 composed of copper or the like are arranged in lines to be attached.

Next, the plural p-type thermoelectric elements 2 and n-type thermoelectric elements 3 are connected to the respective electrodes 4 attached onto the substrate 7b so that the p-type thermoelectric elements 2 and the n-type thermoelectric elements 3 are connected alternately and in series. On this occasion, the plural p-type thermoelectric elements 2 and the plural n-type thermoelectric elements 3 are sandwiched between the two substrates 7a and 7b on which the plural electrodes 4 are attached.

In each of the p-type thermoelectric elements 2, the p-side junction layer 22 is connected to the electrode 4, and in each of the n-type thermoelectric elements 3, the n-side junction layer 32 is connected to the electrode 4. Moreover, each of the p-type thermoelectric elements 2 and each of the n-type thermoelectric elements 3 are connected to the electrode 4 via, for example, a metal paste, such as a silver paste. Note that examples of the metal paste used for junction of the electrode 4 include the silver paste, a gold paste and a platinum paste.

Here, a case in which the electrode 4 is joined by use of the silver paste will be described.

First, the silver paste of a predetermined amount is applied onto the electrode 4.

Subsequently, the p-type thermoelectric element 2 and the n-type thermoelectric element 3 are placed on the silver paste applied onto the electrode 4 and maintained under a vacuum atmosphere at a predetermined first temperature (for example, 100° C.) for a predetermined time (for example, 15 minutes) while being pressurized at a predetermined first pressure (for example, 1 MPa). This volatilizes organic solvent contained in the silver paste.

Next, the temperature is increased from the first temperature to a second temperature (for example, 500° C.), and the p-type thermoelectric element 2 and the n-type thermoelectric element 3 are maintained for a predetermined time (for example, 30 minutes) while being pressurized by a second pressure (for example, 3.7 MPa) higher than the first pressure. Consequently, silver particles contained in the silver paste are aggregated, and thereby the electrode 4 is joined with the p-type thermoelectric element 2 and the n-type thermoelectric element 3 by the silver paste.

Note that, in the thermoelectric module 1 of the exemplary embodiment, a configuration sandwiching the plural p-type thermoelectric conversion elements 2 and the plural n-type thermoelectric conversion elements 3 by the plural electrodes 4 is adopted. Therefore, it is preferable that the thicknesses (heights) in the lamination direction are aligned between the p-type thermoelectric element 2 and the n-type thermoelectric element 3. For that purpose, it is preferable that polishing and grinding for aligning thicknesses are performed in the state of the p-type thermoelectric sintered body or the p-type thermoelectric element 2, and that polishing and grinding for aligning thicknesses are performed in the state of the n-type thermoelectric sintered body or the n-type thermoelectric element 3. Here, for example, in the case of the p-type thermoelectric element 2, it may be possible to polish only one of the two p-side junction layers 22 or to polish both of the two p-side junction layers 22. However, it becomes necessary that each of the both surfaces of the p-type thermoelectric element 2 that is finally obtained is covered with the p-side junction layer 22. Moreover, for example, in the case of the n-type thermoelectric element 3, it may be possible to polish only one of the two n-side junction layers 32 or to polish both of the two n-side junction layers 32. However, it becomes necessary that each of the both surfaces of the n-type thermoelectric element 3 that is finally obtained is covered with the n-side junction layer 32.

When the prepared thermoelectric module 1 is used to generate electric power, the thermoelectric module 1 is disposed with one of the substrates 7a being on the high-temperature side and the other substrate 7b being on the low-temperature side. Then, by applying heat to the thermoelectric module 1 via the high-temperature side substrate 7a and taking heat via the low-temperature side substrate 7b, temperature difference is caused in each p-type thermoelectric element 2 and each n-type thermoelectric element 3, to thereby generate the electromotive force. Then, by applying an electrical resistance load to the two lead wires 6 connected to the electrode 4, current is extracted.

Here, as in the exemplary embodiment, the thermoelectric module 1 using the thermoelectric elements (the p-type thermoelectric elements 2 and the n-type thermoelectric elements 3) including the thermoelectric conversion layers (the p-type thermoelectric conversion layer 20 and the n-type thermoelectric conversion layer 30) composed of alloys having the filled skutterudite structure containing antimony is used in such a manner that the temperature on the high-temperature side is about 400° C. to about 600° C. and the temperature on the low-temperature side is about 50° C. to about 100° C. in many cases.

### Summary of Embodiment 1

In the thermoelectric module 1 of the exemplary embodiment, breakage or cracking of each layer is suppressed in each of the p-type thermoelectric element 2 and the n-type thermoelectric element 3. Moreover, in the exemplary embodiment, in the p-type thermoelectric element 2, it is possible to improve the joint performance between the p-type thermoelectric conversion layer 20 and the p-side junction layer 22 via the p-side intermediate layer 21. Further, in the exemplary embodiment, in the n-type thermoelectric element 3, it is possible to improve the joint performance between the n-type thermoelectric conversion layer 30 and the n-side junction layer 32 via the n-side intermediate layer 31. This makes it possible to improve durability of the thermoelectric module 1.

Moreover, in the exemplary embodiment, in the p-type thermoelectric element 2, the metallic foil was used as the raw materials of the p-side intermediate layer 21 (the p-side first conductor layer 21a and the p-side second conductor layer 21b) laminated on the p-type thermoelectric conversion layer 20 made of powder as the raw material and the p-side junction layer 22. Consequently, as compared to a case where these respective layers are composed of sintered body made of powder as the raw material or a vapor-grown thin film or the like, it becomes possible to simplify the manufacturing process and to reduce unevenness in the thicknesses of the respective layers. As a result, it is possible to suppress generation of pinholes that penetrate through the p-side junction layer 22, which is the outermost layer of the p-type thermoelectric element 2 and used for junction with the electrode 4, in the thickness direction. Moreover, it is possible to suppress generation of pinholes that penetrate through the n-side junction layer 32, which is the outermost layer of the n-type thermoelectric element 3 and used for junction with the electrode 4, in the thickness direction.

### Exemplary Embodiment 2

The exemplary embodiment is almost similar to the exemplary embodiment 1, but different from the exemplary embodiment 1 in part of the configuration of the n-type thermoelectric element 3 and part of the method of manufacturing thereof. Note that, in the exemplary embodiment, those similar to the exemplary embodiment 1 are assigned with same reference signs as the exemplary embodiment 1, and detailed descriptions thereof will be omitted.

### [N-Type Thermoelectric Element]

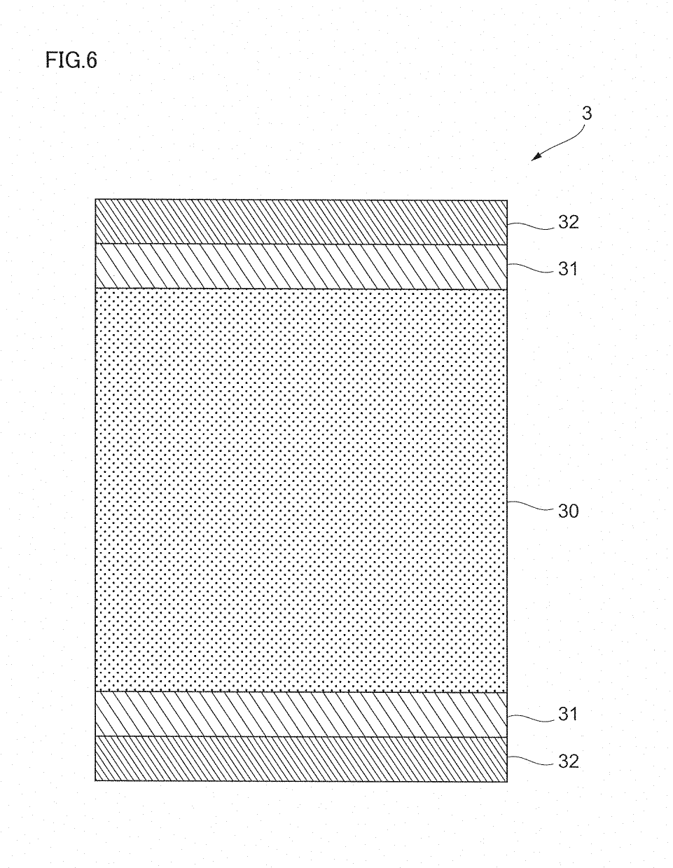

FIG. 6 is a cross-sectional schematic view showing an example of the n-type thermoelectric element 3.

The n-type thermoelectric element 3 of the exemplary embodiment is different from the exemplary embodiment 1 in the point that the n-side intermediate layer 31 includes a single-layer configuration.

(N-Side Intermediate Layer)

The n-side intermediate layer 31 as an example of the intermediate layer is composed of, for example, a layer essentially containing titanium and further containing at least one of aluminum, iron, cobalt and nickel. It is preferable that the n-side intermediate layer 31 contains titanium as a main component and that a content of titanium is 80% by weight or more. Note that the n-side intermediate layer 31 may contain unavoidable impurities contained in raw materials.

The n-side intermediate layer 31 of the exemplary embodiment suppresses diffusion of antimony from the n-type thermoelectric conversion layer 30 and relaxes a thermal stress generated between the n-type thermoelectric conversion layer 30 and the n-side junction layer 32.

The thickness of the n-side intermediate layer 31 is preferably, for example, in the range of 10 μm or more and 100 μm or less.

[Method of Manufacturing n-Type Thermoelectric Element]

Then, a method of manufacturing the n-type thermoelectric element 3 of the exemplary embodiment will be described.

Here, the method of manufacturing the n-type thermoelectric element 3 of the exemplary embodiment is different from the description in the exemplary embodiment 1 in part of details of ‘(2) “Preparation of n-type thermoelectric sintered body”, where the n-type thermoelectric sintered body serves as a base of the n-type thermoelectric element 3’.

(Preparation of n-Type Thermoelectric Sintered Body)

In the exemplary embodiment, similar to the exemplary embodiment 1, the n-type thermoelectric sintered body is prepared by use of the spark plasma sintering method.

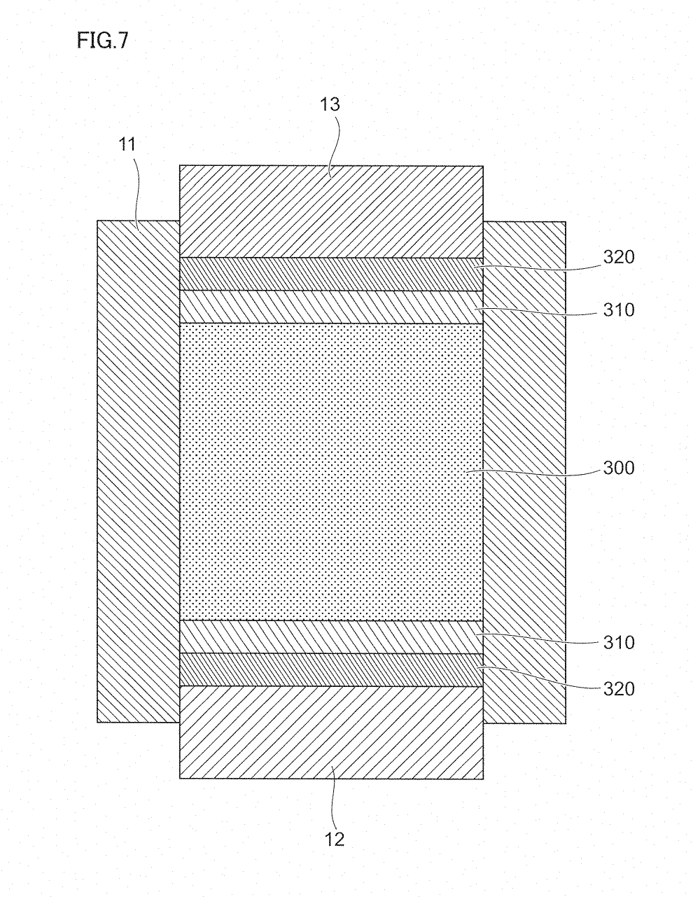

FIG. 7 is a diagram for illustrating the method of preparing the n-type thermoelectric sintered body. To describe more specifically, FIG. 7 shows a cross-sectional configuration of the various types of raw materials of the n-type thermoelectric sintered body before sintering.

In preparation of the n-type thermoelectric sintered body, as the raw materials of the n-type thermoelectric sintered body, the above-described n-type alloy powder 300, mixed metallic powder 310 and two sheets of n-side third metallic foil 320 are used.

Here, as the mixed metallic powder 310 to serve as the n-side intermediate layer 31, titanium powder is used essentially, and further, mixed powder containing at least one of aluminum powder, iron powder, cobalt powder and nickel powder is used. The thickness of the laminated material of the mixed metallic powder 310 in the state shown in FIG. 7 is preferably, for example, 10 μm or more and 100 μm or less.

These types of raw materials are disposed, inside the die 11 between the lower punch 12 and the upper punch 13, in the order of the n-side third metallic foil 320, the mixed metallic powder 310, the n-type alloy powder 300, the mixed metallic powder 310 and the n-side third metallic foil 320 from the lower punch 12 side. On this occasion, a lower surface of the n-side third metallic foil 320 positioned relatively downward is in contact with an upper surface of the lower punch 12, and an upper surface of the n-side third metallic foil 320 positioned relatively upward is in contact with a lower surface of the upper punch 13.

Next, similar to the case of the exemplary embodiment 1, the object in the state shown in FIG. 7 is set in the not-shown spark plasma sintering device, to thereby perform spark plasma sintering. In the case of the n-type thermoelectric sintered body of the exemplary embodiment, it is preferable to set the pressure in the spark plasma sintering to the range of 20 MPa to 30 MPa, and to set the sintering temperature of the order of 700° C.

In this manner, by the spark plasma sintering, the n-type thermoelectric sintered body can be obtained by laminating the n-side junction layer 32 made of the n-side third metallic foil 320, the n-side intermediate layer 31 made of the mixed metallic powder 310, the n-type thermoelectric conversion layer 30 made of the n-type alloy powder 300, the n-side intermediate layer 31 made of the mixed metallic powder 310, and the n-side junction layer 32 made of the n-side third metallic foil 320 in this order and consolidating thereof. At this time, the obtained n-type thermoelectric sintered body shows a disc shape (a tablet shape).

Note that, by use of the p-type thermoelectric elements 2 described in the exemplary embodiment 1, the n-type thermoelectric elements 3 obtained by cutting the n-type thermoelectric sintered body thus obtained and the electrodes 4, the thermoelectric module 1 shown in FIG. 1 can be prepared.

### Summary of Exemplary Embodiment 2

The p-type thermoelectric element 2 of the exemplary embodiment has the same configuration as the exemplary embodiment 1, and therefore, the same effects as the exemplary embodiment 1 can be obtained.

Moreover, with regard to the n-type thermoelectric element 3 of the exemplary embodiment, the n-side intermediate layer 31 is composed of a sintered body of powder (the mixed metallic powder 310); however, the n-side junction layer 32 is, similar to the exemplary embodiment 1, composed of metallic foil. This makes it possible to reduce unevenness in the thickness of the n-side junction layer 32.

### Example

Subsequently, the present invention will be specifically described based on the Example. Note that the present invention is not limited to the following Example.

### Example

(1-1) Preparation of p-Type Alloy Powder

By the above-described strip casting method, a rapidly solidified alloy containing praseodymium, neodymium, iron, nickel and antimony at the ratios (atomic ratios) of 1.2%, 3.4%, 20.3%, 3.6% and 71.5%, and having an average thickness of 0.3 mm was obtained. The p-type alloy powder 200 having the average particle diameter of 100 μm was prepared by milling the obtained rapidly solidified alloy by a disk mill. Here, melting and casting of materials were performed under the argon atmosphere at an atmospheric pressure, and the melting temperature, the cooling speed and the rotation speed of the roll were set at 1450° C., 500° C./sec to 2000° C./sec and 1.0 m/second, respectively.

(1-2) Preparation of p-Type Thermoelectric Sintered Body

Next, inside a glove box set under the argon atmosphere at the atmospheric pressure, the die 11 and the lower punch 12 were placed and the lower punch 12 was attached to the lower side of the opening portion of the die 11. Then, the p-type alloy powder 200 of a predetermined amount was put from above into an inner space in a columnar shape formed by the die 11 and the lower punch 12. Then, the upper punch 13 was attached from above to the opening portion of the die 11, and, by pushing by a hand or the like, the p-type alloy powder 200 in the die 11 was sandwiched by the lower punch 12 and the upper punch 13, to thereby archive uniformity in the thickness of the p-type alloy powder 200.

Subsequently, the die 11, the lower punch 12 and the upper punch 13 containing the p-type alloy powder 200 inside thereof were attached to a molding machine installed in the glove box. Then, by using the molding machine, a pressure of 20 MPa to 30 MPa was applied to the lower punch 12 and the upper punch 13, and thereby the p-type alloy powder 200 sandwiched by these punches was temporarily pressed. Note that the thickness of the laminated material of the p-type alloy powder 200 after temporary pressing was about 3.5 mm.

Next, the die 11, the lower punch 12 and the upper punch 13 containing the p-type alloy powder 200 inside thereof were detached from the molding machine, and further, the upper punch 13 was detached. Then, on one of the surfaces of the temporarily-pressed p-type alloy powder 200 exposed inside the die 11, the p-side first metallic foil 210a, the p-side second metallic foil 210b and the p-side third metallic foil 220 were laminated in this order. Thereafter, the upper punch 13, on the surface of which a releasing agent made of boron nitride powder was applied, was placed from above onto the p-side third metallic foil 220.

Next, the die 11 was turned upside down so that the upper punch 13 was on the lower side and the lower punch 12 was on the upper side, and further, the lower punch 12 was detached. Then, on the other surface of the temporarily-pressed p-type alloy powder 200 exposed inside the die 11, the p-side first metallic foil 210a, the p-side second metallic foil 210b and the p-side third metallic foil 220 were laminated in this order. Thereafter, the lower punch 12, on the surface of which a releasing agent made of boron nitride powder was applied, was placed from above onto the p-side third metallic foil 220. Then, the die 11 was turned upside down again so that the upper punch 13 was on the upper side and the lower punch 12 was on the lower side. As described above, the state shown in FIG. 4 was obtained.

Here, as the p-side first metallic foil 210a, the p-side second metallic foil 210b and the p-side third metallic foil 220, those having the thickness of about 100 μm were respectively used.

Next, the die 11, the lower punch 12 and the upper punch 13 containing the various types of raw materials were taken out of the glove box, and were set in a chamber of a not-shown spark plasma sintering device. Then, by applying a pressure of 20 MPa to 30 MPa to the lower punch 12 and the upper punch 13, the chamber was degassed while pressing the various types of raw materials sandwiched between the punches, and argon gas was introduced into the chamber after degassing.

Subsequently, the pressure applied to the various types of raw materials via the lower punch 12 and the upper punch 13 was increased to 60 MPa, and the DC pulse current was supplied to the lower punch 12 and the upper punch 13 to generate the plasma arc, to thereby perform spark plasma sintering. Here, in the case of the p-type thermoelectric sintered body, the sintering temperature was set at 600° C., and the sintering time (maintaining time) at 600° C. was set to five minutes.

Then, after a lapse of five minutes at 600° C., the pressure applied via the lower punch 12 and the upper punch 13 was reduced to 0 MPa and supply of the DC pulse current was stopped, to thereby perform furnace cooling. After the temperature inside the furnace was lowered to 50° C. or less, the die 11, the lower punch 12 and the upper punch 13 containing the various types of raw materials were taken out of the chamber, and further, the p-type thermoelectric sintered body obtained by applying the spark plasma sintering to the various types of raw materials was taken out.

In the p-type thermoelectric sintered body after sintering, the thickness of the p-type thermoelectric conversion layer 20 was about 3.5 mm, the thickness of the p-side first conductor layer 21a was about 100 μm, the thickness of the p-side second conductor layer 21b was about 100 μm, and the thickness of the p-side junction layer 22 was about 100 μm. Note that both surfaces of the obtained p-type thermoelectric sintered body were polished for adjusting the thickness of the p-type thermoelectric sintered body to 4.0 mm. Consequently, the thickness of the two p-side junction layers 22 in the p-type thermoelectric sintered body after polishing was reduced as compared to those before polishing.

(1-3) Preparation of p-Type Thermoelectric Element

Subsequently, the obtained p-type thermoelectric sintered body was cut by a band saw, and thereby the p-type thermoelectric elements 2, each of which has the lamination structure shown in FIG. 2 and a size of 3.7 mm in length, 3.7 mm in width and 4.0 mm in height, were obtained.

(2-1) Preparation of n-Type Alloy Powder

By the above-described strip casting method, a rapidly solidified alloy containing barium, iron, ytterbium, cobalt and antimony at the ratios (atomic ratios) of 0.4%, 1.4%, 1.4%, 23.2% and 73.6%, and having an average thickness of 0.3 mm was obtained. The n-type alloy powder 300 having the average particle diameter of 100 μm was prepared by milling the obtained rapidly solidified alloy by a disk mill. Here, melting and casting of materials were performed under the argon atmosphere at an atmospheric pressure, and the melting temperature, the cooling speed and the rotation speed of the roll were set at 1450° C., 500° C./sec to 2000° C./sec and 1.0 m/second, respectively.

(2-2) Preparation of n-Type Thermoelectric Sintered Body

Next, inside a glove box set under the argon atmosphere at the atmospheric pressure, the die 11 and the lower punch 12 were placed and the lower punch 12 was attached to the lower side of the opening portion of the die 11. Then, the n-type alloy powder 300 of a predetermined amount was put from above into an inner space in a columnar shape formed by the die 11 and the lower punch 12. Then, the upper punch 13 was attached from above to the opening portion of the die 11, and, by pushing by a hand or the like, the n-type alloy powder 300 in the die 11 was sandwiched by the lower punch 12 and the upper punch 13, to thereby archive uniformity in the thickness of the n-type alloy powder 300.

Subsequently, the die 11, the lower punch 12 and the upper punch 13 containing the n-type alloy powder 300 inside thereof were attached to a molding machine installed in the glove box. Then, by using the molding machine, a pressure of 20 MPa to 30 MPa was applied to the lower punch 12 and the upper punch 13, and thereby the n-type alloy powder 300 sandwiched by these punches was temporarily pressed. Note that the thickness of the laminated material of the n-type alloy powder 300 after temporary pressing was about 3.5 mm.

Next, the die 11, the lower punch 12 and the upper punch 13 containing the n-type alloy powder 300 inside thereof were detached from the molding machine, and further, the upper punch 13 was detached. Then, on one of the surfaces of the temporarily-pressed n-type alloy powder 300 exposed inside the die 11, the n-side first metallic foil 310a, the n-side second metallic foil 310b and the n-side third metallic foil 320 were laminated in this order. Thereafter, the upper punch 13, on the surface of which a releasing agent made of boron nitride powder was applied, was placed from above onto the n-side third metallic foil 320.

Next, the die 11 was turned upside down so that the upper punch 13 was on the lower side and the lower punch 12 was on the upper side, and further, the lower punch 12 was detached. Then, on the other surface of the temporarily-pressed n-type alloy powder 300 exposed inside the die 11, the n-side first metallic foil 310a, the n-side second metallic foil 310b and the n-side third metallic foil 320 were laminated in this order. Thereafter, the lower punch 12, on the surface of which a releasing agent made of boron nitride powder was applied, was placed from above onto the n-side third metallic foil 320. Then, the die 11 was turned upside down again so that the upper punch 13 was on the upper side and the lower punch 12 was on the lower side. As described above, the state shown in FIG. 5 was obtained.

Here, as the n-side first metallic foil 310a, the n-side second metallic foil 310b and the n-side third metallic foil 320, those having the thickness of about 100 μm were respectively used.

Next, the die 11, the lower punch 12 and the upper punch 13 containing the various types of raw materials were taken out of the glove box, and were set in a chamber of a not-shown spark plasma sintering device. Then, by applying a pressure of 20 MPa to 30 MPa to the lower punch 12 and the upper punch 13, the chamber was degassed while pressing the various types of raw materials sandwiched between the punches, and argon gas was introduced into the chamber after degassing.

Subsequently, the pressure applied to the various types of raw materials via the lower punch 12 and the upper punch 13 was increased to 60 MPa, and the DC pulse current was supplied to the lower punch 12 and the upper punch 13 to generate the plasma arc, to thereby perform spark plasma sintering. Here, in the case of the n-type thermoelectric sintered body, the sintering temperature was set at 700° C., and the sintering time (maintaining time) at 700° C. was set to five minutes.

Then, after a lapse of five minutes at 700° C., the pressure applied via the lower punch 12 and the upper punch 13 was reduced to 0 MPa and supply of the DC pulse current was stopped, to thereby perform furnace cooling. After the temperature inside the furnace was lowered to 50° C. or less, the die 11, the lower punch 12 and the upper punch 13 containing the various types of raw materials were taken out of the chamber, and further, the n-type thermoelectric sintered body obtained by applying the spark plasma sintering to the various types of raw materials was taken out.

In the n-type thermoelectric sintered body after sintering, the thickness of the n-type thermoelectric conversion layer 30 was about 3.5 mm, the thickness of the n-side first conductor layer 31a was about 100 μm, the thickness of the n-side second conductor layer 31b was about 100 μm, and the thickness of the n-side junction layer 32 was about 100 μm. Note that both surfaces of the obtained n-type thermoelectric sintered body were polished for adjusting the thickness of the n-type thermoelectric sintered body to 4.0 mm. Consequently, the thickness of the two n-side junction layers 32 in the n-type thermoelectric sintered body after polishing was reduced as compared to those before polishing.

(2-3) Preparation of n-Type Thermoelectric Element

Subsequently, the obtained n-type thermoelectric sintered body was cut by a band saw, and thereby the n-type thermoelectric elements 3, each of which has the lamination structure shown in FIG. 3 and a size of 3.7 mm in length, 3.7 mm in width and 4.0 mm in height, were obtained.

(3) Preparation of Thermoelectric Module

On one surface of the substrate 7a, 18 electrodes 4, each of which was composed of copper with a size of 8.8 mm in length, 4.1 mm in width and 0.5 mm in height, were aligned and attached, and on one surface of the substrate 7b, 19 electrodes 4, each of which was composed of copper and has the aforementioned size, were aligned and attached. Next, a silver paste was applied to have a thickness of 20 μm to 50 μm onto the 18 electrodes 4 attached to the substrate 7a and the 19 electrodes 4 attached to the substrate 7b. Subsequently, 18 pairs of p-type thermoelectric element 2 and n-type thermoelectric element 3 are aligned and placed on the applied silver paste. In other words, the 18 pairs of p-type thermoelectric element 2 and n-type thermoelectric element 3 were sandwiched between the two substrates 7a and 7b on each of which the electrodes 4 were attached. Then, in this state, while applying a pressure of 1 MPa, the substrates, the electrodes and the thermoelectric elements were maintained for 15 minutes under the vacuum atmosphere at 100° C. Subsequently, the temperature was increased to 500° C., the substrates, the electrodes and the thermoelectric elements were maintained for 30 minutes while being pressurized by a pressure of 3.7 MPa.

Consequently, the thermoelectric module 1 with a size of 30 mm in length, 30 mm in width and 6 mm in height, which was composed of the 18 pairs of p-type thermoelectric element 2 and n-type thermoelectric element 3 connected in series by 34 electrodes 4, was obtained.

### Comparative Example

In the Comparative Example, the p-type thermoelectric element 2 was obtained in a manner similar to the Example except for “Preparation of p-type thermoelectric sintered body”, and the n-type thermoelectric element 3 was obtained in a manner similar to the Example except for “Preparation of n-type thermoelectric sintered body”. Moreover, in the Comparative Example, similar to the Example, the electrodes 4 were attached to the p-type thermoelectric elements 2 and the n-type thermoelectric elements 3, to thereby obtain the thermoelectric module 1.

Hereinafter, a description will be given of preparation of the p-type thermoelectric sintered body and preparation of the n-type thermoelectric sintered body in the Comparative Example. However, in the Comparative Example, after a sintered body including the p-type thermoelectric conversion layer 20 is prepared by the spark plasma sintering, the p-side junction layer 22 and others are laminated on the sintered body by a PVD method. Moreover, in the Comparative Example, after a sintered body including the n-type thermoelectric conversion layer 30 is prepared by the spark plasma sintering, the n-side junction layer 32 and others are laminated on the sintered body by the PVD method. Then, in the Comparative Example, the item formed by separately laminating the p-side junction layer 22 and the like on the sintered body including the p-type thermoelectric conversion layer 20 is referred to as “p-side thermoelectric sintered body”, and the item formed by separately laminating the n-side junction layer 32 and the like on the sintered body including the n-type thermoelectric conversion layer 30 is referred to as “n-side thermoelectric sintered body”.

(a) Preparation of p-Type Thermoelectric Sintered Body

Inside a glove box set under the argon atmosphere at the atmospheric pressure, the die 11 and the lower punch 12 were placed and the lower punch 12 was attached to the lower side of the opening portion of the die 11. Then, material powder of the p-side second conductor layer 21b composed of titanium powder with an average particle diameter of 15 μm, material powder of the p-side first conductor layer 21a composed of iron powder with an average particle diameter of 70 μm, the p-type alloy powder 200 with an average particle diameter of 100 μm, the above-described material powder of the p-side first conductor layer 21a and the above-described material powder of the p-side second conductor layer 21b were put from above into an inner space in a columnar shape formed by the die 11 and the lower punch 12. Then, the upper punch 13 was attached from above to the opening portion of the die 11, and, by pushing by a hand or the like, the various types of raw materials in the die 11 were sandwiched by the lower punch 12 and the upper punch 13, to thereby archive uniformity in the thicknesses of the material powder of the p-side second conductor layer 21b, the material powder of the p-side first conductor layer 21a and the p-type alloy powder 200.

Next, the die 11, the lower punch 12 and the upper punch 13 containing the various types of raw materials were taken out of the glove box, and were set in a chamber of a not-shown spark plasma sintering device. Then, by applying a pressure of 20 MPa to 30 MPa to the lower punch 12 and the upper punch 13, the chamber was degassed while pressing the various types of raw materials sandwiched between the punches, and argon gas was introduced into the chamber after degassing.

Subsequently, the pressure applied to the various types of raw materials via the lower punch 12 and the upper punch 13 was increased to 60 MPa, and the DC pulse current was supplied to the lower punch 12 and the upper punch 13 to generate the plasma arc, to thereby perform spark plasma sintering. Here, in the case of the p-type thermoelectric sintered body, the sintering temperature was set at 600° C., and the sintering time (maintaining time) at 600° C. was set to five minutes.

Then, after a lapse of five minutes at 600° C., the pressure applied via the lower punch 12 and the upper punch 13 was reduced to 0 MPa and supply of the DC pulse current was stopped, to thereby perform furnace cooling. After the temperature inside the furnace was lowered to 50° C. or less, the die 11, the lower punch 12 and the upper punch 13 containing the various types of raw materials were taken out of the chamber, and further, the sintered body obtained by applying the spark plasma sintering to the various types of raw materials was taken out.

In the sintered body after sintering, the thickness of the p-type thermoelectric conversion layer 20 was about 3.5 mm, the thickness of the p-side first conductor layer 21a was about 150 μm and the thickness of the p-side second conductor layer 21b was about 100 μm.

Next, by the PVD method, more specifically, by a series of sputtering methods, on each of the two p-side second conductor layers 21b of the p-type thermoelectric sintered body, a titanium nitride layer, a titanium layer and a p-side junction layer 22 composed of copper were laminated in the order, and thereby the p-side thermoelectric sintered body was obtained.

Here, lamination of the titanium nitride layer was performed for 30 minutes by supplying a mixed gas of a nitrogen gas (125 cm³/min) and an argon gas (75 cm³/min) as a flow gas at a pressure of 2.6 Pa and setting the atmospheric temperature at 450° C.

Moreover, lamination of the titanium layer was performed for five minutes by supplying an argon gas (75 cm³/min) as a flow gas at a pressure of 2.2 Pa and setting the atmospheric temperature at 450° C.

Further, lamination of the p-side junction layer 22 was performed for 30 minutes by supplying an argon gas (75 cm³/min) as a flow gas at a pressure of 2.2 Pa and setting the atmospheric temperature at 450° C.

As described above, the p-type thermoelectric element 2 of the Comparative Example was obtained.

Here, the thickness of the titanium nitride layer was 2 μm to 5 μm, the thickness of the titanium layer was 1 μm and the thickness of the p-side junction layer 22 composed of copper was 2 μm to 5 μm.

Note that, in the p-type thermoelectric element 2 of the Comparative Example, the reason why the titanium nitride layer and the titanium layer are provided between the p-side second conductor layer 21b composed of titanium and the p-side junction layer 22 composed of copper is as follows. Because, when the p-side junction layer 22 composed of copper is directly laminated by the PVD method on the p-side second conductor layer 21b prepared by sintering the titanium powder, due to low joint performance therebetween, peeling is likely to occur.

(b) Preparation of n-Type Thermoelectric Sintered Body

Inside a glove box set under the argon atmosphere at the atmospheric pressure, the die 11 and the lower punch 12 were placed and the lower punch 12 was attached to the lower side of the opening portion of the die 11.

Then, material powder (mixed powder) of the n-side intermediate layer 31 composed of titanium powder with an average particle diameter of 44 μm and aluminum powder with an average particle diameter of 5 μm, the n-type alloy powder 300 with an average particle diameter of 100 μm and the above-described material powder of the n-side intermediate layer 31 were put from above into an inner space in a columnar shape formed by the die 11 and the lower punch 12. Then, the upper punch 13 was attached from above to the opening portion of the die 11, and, by pushing by a hand or the like, the various types of raw materials in the die 11 was sandwiched by the lower punch 12 and the upper punch 13, to thereby archive uniformity in the thicknesses of the material powder of the n-side intermediate layer 31 and the n-type alloy powder 300.

Next, the die 11, the lower punch 12 and the upper punch 13 containing the various types of raw materials were taken out of the glove box, and were set in a chamber of a not-shown spark plasma sintering device. Then, by applying a pressure of 20 MPa to 30 MPa to the lower punch 12 and the upper punch 13, the chamber was degassed while pressing the various types of raw materials sandwiched between the punches, and argon gas was introduced into the chamber after degassing.

Subsequently, the pressure applied to the various types of raw materials via the lower punch 12 and the upper punch 13 was increased to 60 MPa, and the DC pulse current was supplied to the lower punch 12 and the upper punch 13 to generate the plasma arc, to thereby perform spark plasma sintering. Here, in the case of the n-type thermoelectric sintered body, the sintering temperature was set at 700° C., and the sintering time (maintaining time) at 700° C. was set to five minutes.

Then, after a lapse of five minutes at 700° C., the pressure applied via the lower punch 12 and the upper punch 13 was reduced to 0 MPa and supply of the DC pulse current was stopped, to thereby perform furnace cooling. After the temperature inside the furnace was lowered to 50° C. or less, the die 11, the lower punch 12 and the upper punch 13 containing the various types of raw materials were taken out of the chamber, and further, the sintered body obtained by applying the spark plasma sintering to the various types of raw materials was taken out.

In the sintered body after sintering, the thickness of the n-type thermoelectric conversion layer 30 was about 3.5 mm and the thickness of the n-side intermediate layer 31 was about 200 μm.

Next, by the PVD method, more specifically, by a series of sputtering methods, on each of the two n-side intermediate layers 31 of the n-type thermoelectric sintered body, a titanium nitride layer, a titanium layer and an n-side junction layer 32 composed of copper were laminated in the order, and thereby the n-side thermoelectric sintered body was obtained.

Note that the lamination condition of the n-side junction layer 32 composed of these titanium nitride layer, titanium layer and copper layer was set equal to the lamination condition of the p-side junction layer 22 composed of the titanium nitride layer, the titanium layer and the copper layer in the preparation of the p-type thermoelectric sintered body of the Comparative Example.

As described above, the n-type thermoelectric element 3 of the Comparative Example was obtained.

Here, the thickness of the titanium nitride layer was 2 μm to 5 μm, the thickness of the titanium layer was 1 μm and the thickness of the n-side junction layer 32 composed of copper was 2 μm to 5 μm.

### <Evaluation>

(Unevenness in Thickness of Each Layer)

First, in the Example and the Comparative Example, a cross section of each of the p-type thermoelectric element 2 and the n-type thermoelectric element 3 was observed.

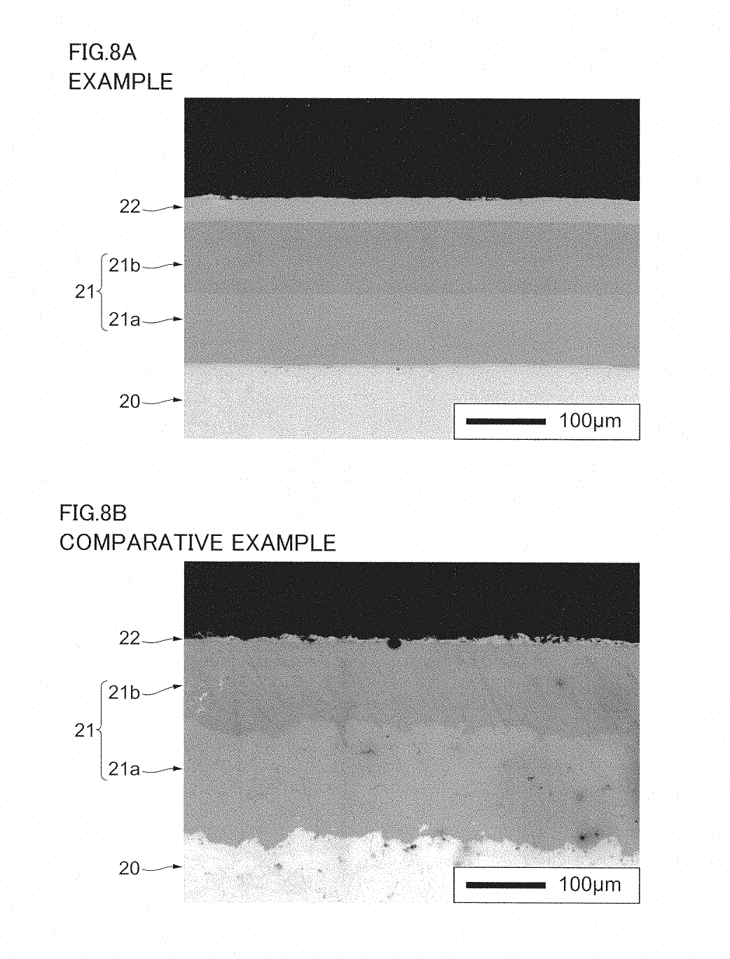

FIG. 8A is a cross-sectional photograph of the p-type thermoelectric element 2 of the Example taken by an SEM (Scanning Electron Microscope), and FIG. 8B is a cross-sectional photograph of the p-type thermoelectric element 2 of the Comparative Example taken by the SEM. Here, in the p-type thermoelectric element 2 of the Example, due to polish applied to the p-side junction layer 22, the p-side junction layer 22 becomes thinner than the p-side first conductor layer 21a and the p-side second conductor layer 21b. Note that, in the p-type thermoelectric element 2 of the Comparative Example, there are, in actuality, the titanium nitride layer and the titanium layer between the p-side second conductor layer 21b and the p-side junction layer 22; however, here, the description of p-side junction layer 22 includes the titanium nitride layer and the titanium layer.

In the p-type thermoelectric element 2 of the Example, all of the p-side first conductor layer 21a, the p-side second conductor layer 21b and the p-side junction layer 22 are composed of metallic foil. On the other hand, in the p-type thermoelectric element 2 of the Comparative Example, both of the p-side first conductor layer 21a and the p-side second conductor layer 21b are composed of the sintered body of metallic powder, and titanium nitride layer, the titanium layer and the p-side junction layer 22 are composed of deposits of metal by the PVD method.

From FIGS. 8A and 8B, in the p-type thermoelectric element 2 of the Example, it can be learned that an interface between the p-type thermoelectric conversion layer 20 and the p-side first conductor layer 21a, and interface between the p-side first conductor layer 21a and the p-side second conductor layer 21b and an interface between the p-side second conductor layer 21b and the p-side junction layer 22 are flat as compared to those of the p-type thermoelectric element 2 of the Comparative Example. In other words, in the p-type thermoelectric element 2 of the Example, unevenness in the thickness of each of the p-side first conductor layer 21a, the p-side second conductor layer 21b and the p-side junction layer 22 is reduced as compared to that of the p-type thermoelectric element 2 of the Comparative Example.

Moreover, from FIGS. 8A and 8B, the density of each of the p-side first conductor layer 21a, the p-side second conductor layer 21b and the p-side junction layer 22 in the p-type thermoelectric element 2 of the Example is high as compared to that of the p-type thermoelectric element 2 in the Comparative Example. In other words, in the p-type thermoelectric element 2 of the Example, the number of holes in each of the p-side first conductor layer 21a, the p-side second conductor layer 21b and the p-side junction layer 22 is reduced as compared to that of the p-type thermoelectric element 2 of the Comparative Example.

Note that, though detailed description is not given here, the results similar to those related to the p-type thermoelectric element 2 was obtained related to the n-type thermoelectric element 3.

(Surface State of Junction Layer)

Next, in the Example and the Comparative Example, a surface state of the outermost layer of each of the p-type thermoelectric element 2 and the n-type thermoelectric element 3 (the p-side junction layer 22 and the n-type junction layer 32) was observed.

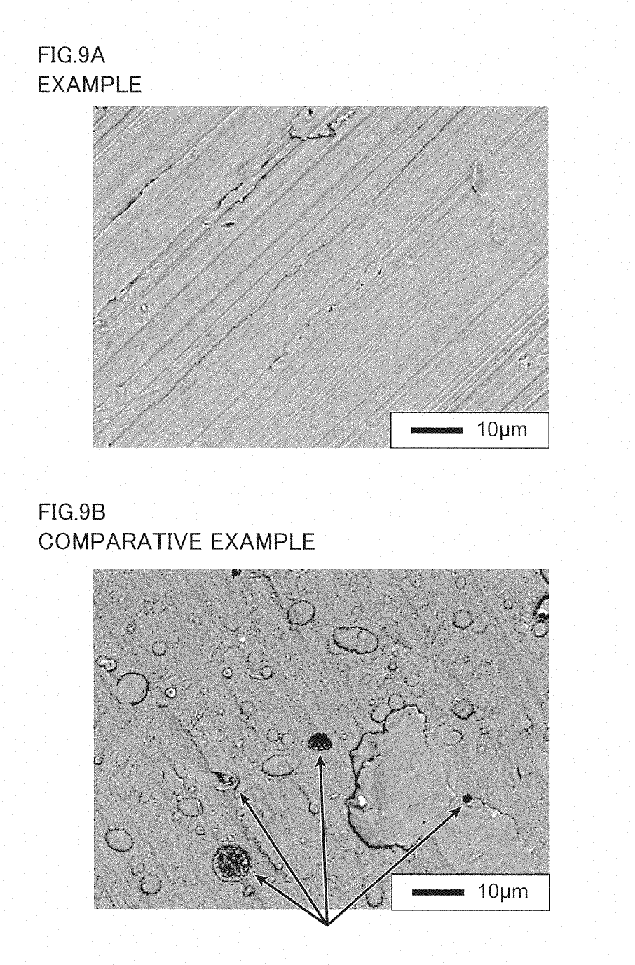

FIG. 9A is a surface photograph of the p-side junction layer 22 of the Example taken by the SEM, and FIG. 9B is a surface photograph of the i-side junction layer 22 of the Comparative Example taken by the SEM.

From FIGS. 9A and 9B, it can be learned that, in the p-side junction layer 22 of the Example, asperities on the surface thereof are small as compared to those of the p-side junction layer 22 of the Comparative Example. In other words, areas showing graininess are hardly seen in the p-side junction layer 22 of the Example, whereas there are many areas showing graininess in the p-side junction layer 22 of the Comparative Example.

Moreover, in taking the SEM photographs shown in FIGS. 9A and 9B, elemental mapping by an EDS (Energy Dispersive X-ray Spectrometer) was carried out. Then, in the p-type thermoelectric element 2 of the Example, all areas of the outermost layer were composed of copper, whereas, in the p-type thermoelectric element 2 of the Comparative Example, in a part of the outermost layer, there were areas showing low density of copper and high density of titanium (refer to blackened areas indicated by arrows in FIG. 9B). Here, copper is the element composing the p-side junction layer 22, and titanium is the element composing the p-side second conductor layer 21b existing on the backside of the p-side junction layer 22. Therefore, it can be considered that the areas in which the density of titanium is higher than the density of copper in the p-type thermoelectric element 2 of the Comparative Example are assumed to be the areas in which pinholes are formed in the p-side junction layer 22. In this manner, in the p-type thermoelectric element 2 of the Example, easiness of occurrence of pinholes in the p-side junction layer 22 is reduced as compared to the p-type thermoelectric element 2 of the Comparative Example.

Note that, though detailed description is not given here, the results similar to those related to the p-type thermoelectric element 2 was obtained related to the n-type thermoelectric element 3.

The foregoing description of the present exemplary embodiments of the present invention has been provided for the purposes of illustration and description. It is not intended to be exhaustive or to limit the invention to the precise forms disclosed. Obviously, many modifications and variations will be apparent to practitioners skilled in the art. The present exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

1. A thermoelectric element comprising:
a thermoelectric conversion layer that is composed of an alloy including a filled skutterudite structure;
a junction layer that is composed of metallic foil containing copper and used for electrical junction with outside; and
an intermediate layer that is composed of metallic foil and provided between the thermoelectric conversion layer and the junction layer.

2. The thermoelectric element according to claim 1, wherein
the intermediate layer comprises:
a stress relaxation layer that is provided on a side facing the thermoelectric conversion layer to relax a stress of the thermoelectric conversion layer; and
a diffusion suppression layer that is provided on a side facing the junction layer to suppress diffusion of elements between the thermoelectric conversion layer and the junction layer.

3. The thermoelectric element according to claim 2, wherein,
when the thermoelectric conversion layer is composed of an alloy including a filled skutterudite structure represented by REₓ(Fe_{1-y}M_{y})₄Sb₁₂, where RE is at least one type selected from rare-earth elements, M is at least one type selected from a group of Co and Ni, 0.01≤x≤1, and 0≤y≤0.5,
the stress relaxation layer of the intermediate layer is composed of metallic foil containing iron, and
the diffusion suppression layer of the intermediate layer is composed of metallic foil containing titanium.

4. The thermoelectric element according to claim 2, wherein,
when the thermoelectric conversion layer is composed of an alloy including a filled skutterudite structure represented by Rₓ(Co_{1-y}M_{y})₄Sb₁₂, where R is at least one type selected from group II elements or rare-earth elements, M is at least one type selected from a group of Fe and Ni, 0.01≤x≤1 and 0≤y≤0.3,
the stress relaxation layer of the intermediate layer is composed of metallic foil containing cobalt or metallic foil containing nickel, and
the diffusion suppression layer of the intermediate layer is composed of metallic foil containing titanium.

5. A thermoelectric element comprising:
a thermoelectric conversion layer that is composed of an alloy including a filled skutterudite structure containing cobalt and at least one type selected from group II elements or rare-earth elements;
a junction layer that is composed of metallic foil containing copper and used for electrical junction with outside; and
an intermediate layer essentially containing titanium, and further containing at least one of aluminum, iron, cobalt and nickel, and provided between the thermoelectric conversion layer and the junction layer.

6. A thermoelectric module comprising:
thermoelectric elements and electrodes electrically connected to the thermoelectric elements, wherein
each of the thermoelectric elements comprises:
a thermoelectric conversion layer that is composed of an alloy including a filled skutterudite structure;
a junction layer that is composed of metallic foil containing copper and used for electrical junction with one of the electrodes; and
an intermediate layer that is composed of metallic foil and provided between the thermoelectric conversion layer and the junction layer.
